(19) United States
(12) Patent Application Publication
(10) Pub. No.: US 2026/0229265 A1
(43) Pub. Date: Aug. 6, 2026

(54) CROSS-POINT ARRAY LEAKAGE COMPENSATION

(71) Applicant: Sandisk Technologies, Inc., Milpitas, CA (US)

(72) Inventor: Juan P. Saenz, Menlo Park, CA (US)

(73) Assignee: Sandisk Technologies, Inc., Milpitas, CA (US)

(21) Appl. No.: 19/046,326

(22) Filed: Feb. 5, 2025

(51) Int. Cl. G11C 11/16; H10B 61/00

(52) U.S. Cl. CPC G11C 11/165; G11C 11/1673; G11C 11/1675; H10B 61/10

(57) ABSTRACT

Technology for a system and method for controlling leakage current in a cross-point array having programmable resistance memory cells. The slope of a trailing edge of a pulse that is applied to a selected memory cell may depend on a wear factor of the selected memory cell. The wear factor may be based on a number of times the selected memory cell has been accessed by writes and/or reads. The memory system may flatten the slope of the trailing edge of the pulse as the selected memory cell experiences more wear.

### BACKGROUND

Memory is widely used in various electronic devices such as cellular telephones, digital cameras, personal digital assistants, medical electronics, mobile computing devices, non-mobile computing devices, and data servers. Memory may comprise non-volatile memory or volatile memory. A non-volatile memory allows information to be stored and retained even when the non-volatile memory is not connected to a source of power (e.g., a battery). Non-volatile memory can be made to appear non-volatile at least for a limited time by, external to the memory chip, adding battery back to the power supply.

The memory cells may reside in a cross-point memory array. In a memory array with a cross-point type architecture, one set of conductive lines run across the surface of a substrate and another set of conductive lines are formed above the other set of conductive lines running in an orthogonal direction relative to the initial layer. The memory cells are located at the cross-point junctions of the two sets of conductive lines. Cross-point memory arrays are sometimes referred to as cross-bar memory arrays.

The cross-point memory array may contain programmable resistance memory cells. A programmable resistance memory cell is formed from a material having a programmable resistance. In a binary approach, the programmable resistance memory cell can be programmed into one of two resistance states: high resistance state (HRS) and low resistance state (LRS). In some approaches, more than two resistance states may be used. A number of types of programmable resistance memory cells have been proposed. One type of programmable resistance memory cell is a magnetoresistive random access memory (MRAM) cell. An MRAM cell uses magnetization to represent stored data, in contrast to some other memory technologies that use electronic charges (DRAM) or voltages (SRAM) to store data. A bit of data is written to an MRAM cell by changing the direction of magnetization of a magnetic element (“the free layer”) within the MRAM cell, and a bit is read by measuring the resistance of the MRAM cell, such resistance changing with the direction of magnetization. However, the cross-point memory array may have other types of memory cells. For example, the cross-point memory array may have memory cell of other technologies such as ReRam, PCM (Phase Change Memory), or FeRam.

Some programmable resistance memory cells in a cross-point array have a threshold switching selector in series with the programmable resistance memory element. The threshold switching selector has a high resistance in an off or non-conductive state until it is biased to a voltage higher than its threshold voltage (Vth) or current above its threshold current, (It), and until its voltage bias falls below Vhold (“Voffset”) or current below a holding current Ihold. After the Vth is exceeded and while Vhold is exceeded across the threshold switching selector, the threshold switching selector has a significantly lower resistance (in an on or conductive state). The threshold switching selector remains on until its current is lowered below a holding current Ihold, or the voltage is lowered below a holding voltage, Vhold. When this occurs, the threshold switching selector returns to the off (higher) resistance state. To read a memory cell, the threshold switching selector is activated by being turned on before the resistance state of the memory cell is determined. One example of a threshold switching selector is an Ovonic Threshold Switch (OTS). Other examples of threshold switching selectors include, but are not limited to, Volatile Conductive Bridge (VCB), Metal-Insulator-Metal (MIM), or other material that provides a highly non-linear dependence of current on select voltage.

During typical operation of a cross-point array one, or at most a few, memory cells are selected for operation. A memory cell may be selected by causing a voltage across the memory cell that is at least as high as the Vth of the threshold switching selector. This voltage will be referred to as a select voltage (Vs). Most of the memory cells will receive a voltage that is well below Vs (and also below the Vth of the threshold switching selector). Some of these unselected memory cells are fully unselected meaning that a voltage at or near OV appears across the memory cell. However, a significant number of the memory cells are “half-selected” meaning that about Vs/2 appears across the “half-selected cell”. The Vth of the half-selected cell should be above Vs/2 such that the threshold switching selector does not turn on. However, even if the voltage applied to the threshold switching selector is below the Vth, the threshold switching selector will still have a small current. The leakage current in half-selected cells is especially significant. The total current of all of the threshold switching selectors that should be off is referred to as the “leakage current.” This leakage current can impair memory operations in the cross-point array. For example, the leakage current can result in IR drops along a word line and/or bit line that lowers the intended voltage to be applied to the selected memory cell.

### BRIEF DESCRIPTION OF THE DRAWINGS

Like-numbered elements refer to common components in the different figures.

FIG. 1 is a block diagram of one embodiment of a non-volatile memory system connected to a host.

FIG. 2 is a block diagram of one embodiment of a memory die.

FIG. 3 is a block diagram of one embodiment of an integrated memory assembly containing a control die and a memory structure die.

FIG. 4A depicts one embodiment of a portion of a memory array that forms a cross-point architecture in an oblique view.

FIGS. 4B and 4C respectively present side and top views of the cross-point structure in FIG. 4A.

FIG. 4D depicts an embodiment of a portion of a two-level memory array that forms a cross-point architecture in an oblique view.

FIG. 5A illustrates an embodiment for the structure of an MRAM memory cell having a threshold switching selector.

FIG. 5B illustrates an embodiment for the structure of a selector only memory cell.

FIGS. 6A and 6B illustrate embodiments for the incorporation of threshold switching selectors into an MRAM memory array having a cross-point architecture.

FIG. 7 depicts an embodiment of a memory array having a cross-point architecture with a selected cell, half-selected cells, and full unselected cells.

FIG. 8 depicts a conventional pulse that may be applied to a programmable resistance memory cell in a cross point array.

FIG. 9 depicts a pulse that is applied to a programmable resistance memory cell in a cross point array by an embodiment of a memory system.

FIG. 10 depicts a pulse that is applied to a programmable resistance memory cell in a cross point array by an embodiment of a memory system.

FIG. 11 depicts plots of leakage current versus stress cycles.

FIG. 12 depicts leakage current versus critical dimension (CD) of the memory cells for two different slopes of the trailing edge of the pulse applied to the selected memory cell.

FIGS. 13A and 13B depict voltage pulses applied to a memory cell by an embodiment of a memory system.

FIGS. 14A and 14B depict current pulses applied to a memory cell by an embodiment of a memory system.

FIG. 15 is a flowchart of one embodiment of a process for reducing leakage current when operating a cross-point array.

FIG. 16 is a flowchart of one embodiment of a process for reducing leakage current when operating a cross-point array.

FIG. 17 is a flowchart of one embodiment of a process for reducing leakage current when operating a cross-point array.

FIG. 18 depicts plots of threshold switching selector Vth versus critical dimension (CD).

FIG. 19 is a block level diagram of an embodiment of components for generating a pulse having target slope for the TE.

### DETAILED DESCRIPTION

Technology is disclosed for a memory system and method for controlling leakage current in a cross-point array having programmable resistance memory cells. In an embodiment, the slope of a trailing edge of a pulse that is applied to a selected memory cell depends on a wear factor of the selected memory cell. The wear factor may be based on a number of times the selected memory cell has been accessed by writes and/or reads. The memory system may flatten the slope of the trailing edge of the pulse as the selected memory cell experiences more wear. Without any change to the pulse applied to the selected memory cell the leakage current may increase with increased wear to the memory cell. Flattening the slope of the trailing edge of the pulse mitigates the potential increase in leakage current in the cross-point array.

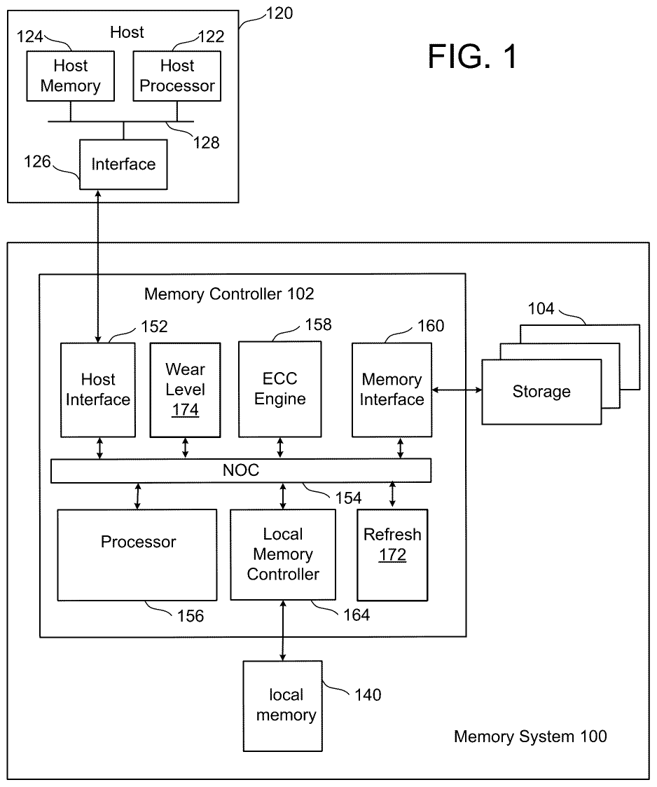

FIG. 1 is a block diagram of one embodiment of a non-volatile memory system (or more briefly “memory system”) 100 connected to a host system 120. Memory system 100 can implement the technology presented herein for performing memory operations on programmable resistance memory cells in a cross-point array. In an embodiment, the memory cells have a programmable resistance memory element (e.g., MRAM element) in series with a threshold switching selector such as an OTS. In an embodiment, the memory cells are “selector only memory cells” in which the threshold switching selector serves as both a selector and the programmable resistance memory element. Many types of memory systems can be used with the technology proposed herein. Example memory systems include dual in-line memory modules (DIMMs), solid state drives (“SSDs”), memory cards and embedded memory devices; however, other types of memory systems can also be used.

Memory system 100 of FIG. 1 comprises a memory controller 102, memory 104 for storing data, and local memory 140 (e.g., MRAM, ReRAM, DRAM). The local memory 140 may be non-volatile and retain data after power off. The local memory 140 may be volatile and not be expected to retain data after power off. In one embodiment the local memory 140 is MRAM. In an embodiment, the local memory MRAM is not required to retain data after power-off. However, the local memory MRAM may retain data after power-off. In one embodiment, memory controller 102 and/or local memory controller 164 provides access to programmable resistance memory cells in local memory 140. For example, memory controller 102 may provide for access in a cross-point array of MRAM cells in local memory 140. In another embodiment the memory controller 102 or interface 126 or both are eliminated and the memory packages are connected directly to the host 120 through a bus such as DDRn. Or they are connected to a host memory management unit (MMU). In another instance, the memory controller 102 or portions are moved onto the memory 104 for direct connection of the memory 104 to the host, such as by providing parity bits, ECC, and wear level on the memory 104 along with an DDRn interface to/from the host 120 or MMU. The term memory system, as used throughout this document, is not limited to memory system 100. For example, the local memory 140 or the combination of local memory 140 and local memory controller 164 could be considered to be a memory system. Likewise, host memory 124 or the combination of host processor 122 and host memory 124 considered to be a memory system.

The components of memory system 100 depicted in FIG. 1 are electrical circuits. The memory controller 102 has host interface 152, processor 156, ECC engine 158, memory interface 160, local memory controller 164, refresh logic 172, and wear level 174. The host interface 152 is connected to and in communication with host 120. Host interface 152 is also connected to a network-on-chip (NOC) 154. A NOC is a communication subsystem on an integrated circuit. NOC's can span synchronous and asynchronous clock domains or use unclocked asynchronous logic. NOC technology applies networking theory and methods to on-chip communications and brings notable improvements over conventional bus and crossbar interconnections. NOC improves the scalability of systems on a chip (SoC) and the power efficiency of complex SoCs compared to other designs. The wires and the links of the NOC are shared by many signals. A high level of parallelism is achieved because all links in the NOC can operate simultaneously on different data packets. Therefore, as the complexity of integrated subsystems keep growing, a NOC provides enhanced performance (such as throughput) and scalability in comparison with previous communication architectures (e.g., dedicated point-to-point signal wires, shared buses, or segmented buses with bridges). In other embodiments, NOC 154 can be replaced by a bus. Connected to and in communication with NOC 154 is processor 156, ECC engine 158, memory interface 160, local memory controller 164, refresh logic 172, and wear level 174. Local memory controller 164 is used to operate and communicate with local high speed memory 140 (e.g., MRAM). In other embodiments, local high speed memory 140 can be DRAM, SRAM or another type of volatile memory.

ECC engine 158 performs error correction services. For example, ECC engine 158 performs data encoding and decoding of parity bits provided on or off the memory as part of the code word used for error correction of the data fetched from memory 140 or 104. In one embodiment, ECC engine 158 is an electrical circuit programmed by software. For example, ECC engine 158 can be a processor that can be programmed. In other embodiments, ECC engine 158 is a custom and dedicated hardware circuit without any software. In one embodiment, the function of ECC engine 158 is implemented by processor 156. In one embodiment, local memory 140 has an ECC engine with or without a wear level engine. In one embodiment, memory 104 has an ECC engine with or without a wear level engine.

Processor 156 performs the various controller memory operations, such as programming, erasing, reading, and memory management processes including wear level. A separate wear level 174 is depicted, but the wear level 174 may be implemented by processor 156. Also, refresh logic 172 is depicted, but the refresh may also be implemented by the processor 156. In one embodiment, processor 156 is programmed by firmware. In other embodiments, processor 156 is a custom and dedicated hardware circuit without any software. Processor 156 also implements a translation module, as a software/firmware process or as a dedicated hardware circuit. In many systems, the non-volatile memory is addressed internally to the storage system using physical addresses associated with the one or more memory die. However, the host system will use logical addresses to address the various memory locations. This enables the host to assign data to consecutive logical addresses, while the storage system is free to store the data as it wishes among the locations of the one or more memory dies. To implement this system, memory controller 102 (e.g., the translation module) performs address translation between the logical addresses used by the host and the physical addresses used by the memory die. One example implementation is to maintain tables (i.e., the L2P tables mentioned above) that identify the current translation between logical addresses and physical addresses. An entry in the L2P table may include an identification of a logical address and corresponding physical address. Although logical address to physical address tables (or L2P tables) include the word “tables” they need not literally be tables. Rather, the logical address to physical address tables (or L2P tables) can be any type of data structure. In some examples, the memory space of a storage system is so large that the local memory 140 cannot hold all of the L2P tables. In such a case, the entire set of L2P tables are stored in memory 104 and a subset of the L2P tables are cached (L2P cache) in the local high speed memory 140.

Memory interface 160 communicates with storage 104. In an embodiment, storage 104 contains programmable resistance memory cells in a cross-point array. In an embodiment, storage 104 contains NAND memory cells. In one embodiment, memory interface provides a Toggle Mode interface. Other interfaces can also be used. In some example implementations, memory interface 160 (or another portion of controller 102) implements a scheduler and buffer for transmitting data to and receiving data from one or more memory die.

In one embodiment, local memory 140 has an ECC engine. Local memory 140 may be used to help perform other functions such as wear leveling. Further details of on-chip memory maintenance are described in U.S. Pat. No. 10,545,692, titled “Memory Maintenance Operations During Refresh Window”, and U.S. Pat. No. 10,885,991, titled “Data Rewrite During Refresh Window”, both of which are hereby incorporated by reference in their entirety. In an embodiment, the local memory 140 is synchronous. In an embodiment, the local memory 140 is asynchronous.

In one embodiment, storage 104 comprises a plurality of memory packages. Each memory package includes one or more memory dies. Therefore, memory controller 102 is connected to one or more memory dies. In one embodiment, the memory package can include types of memory, such as storage class memory (SCM) based on programmable resistance random access memory (such as ReRAM, MRAM, FeRAM or RRAM) or a phase change memory (PCM). In one embodiment, memory controller 102 provides access to memory cells in a cross-point array in a storage 104.

Memory controller 102 communicates with host 120 via an interface 152 that implements a protocol such as, for example, Compute Express Link (CXL). Or such controller can be eliminated and the memory packages can be placed directly on the host bus, DDRn or CXL for examples. For working with memory system 100, host system 120 includes a host processor 122, host memory 124, and interface 126 connected along bus 128. Host memory 124 is the host's physical memory, and can be DRAM, SRAM, ReRAM, MRAM, non-volatile memory, or another type of storage. In an embodiment, host memory 124 contains a cross-point array of programmable resistance memory cells, with each memory cell comprising a programmable resistance memory element and a threshold switching selector in series with the programmable resistance memory element.

Host 120 is external to and separate from memory system 100. In one embodiment, memory system 100 is embedded in host 120. Host memory 124 may be referred to herein as a memory system. The combination of the host processor 122 and host memory 124 may be referred to herein as a memory system. In an embodiment, such host memory can be cross-point memory using MRAM.

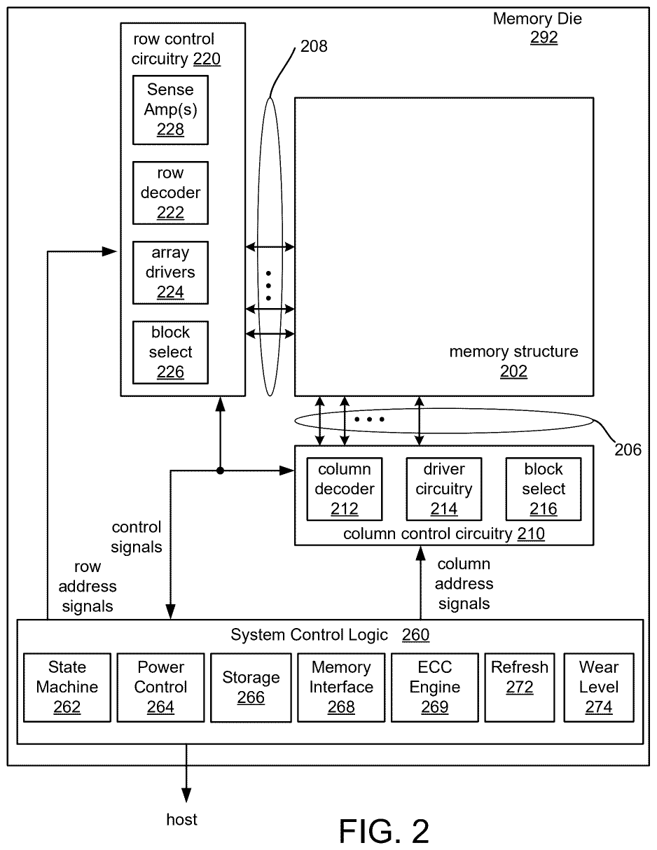

FIG. 2 is a block diagram that depicts one example of a memory die 292 that can implement the technology described herein. In one embodiment, memory die 292 is included in local memory 140, and in embodiment memory die 292 is included in storage 104. In one embodiment, memory die 292 is included in host memory 124. Memory die 292 includes a memory structure 202 that can include any of memory cells described in the following. The memory structure 202 may include one or more memory arrays. The array terminal lines of memory structure 202 include the various layer(s) of word lines organized as rows, and the various layer(s) of bit lines organized as columns. However, other orientations can also be implemented, including for example diagonal patterns to save space. Memory die 292 includes row control circuitry 220, whose outputs 208 are connected to respective word lines of the memory structure 202. Row control circuitry 220 receives a group of M row address signals and one or more various control signals from System Control Logic circuit 260, and typically may include such circuits as row decoders 222, row drivers 224, and block select circuitry 226 for both reading and writing operations. Row control circuitry 220 may also include read/write circuitry. In an embodiment, row control circuitry 220 has sense amplifiers 228, which each contain circuitry for sensing a condition (e.g., voltage) of a word line of the memory structure 202. In an embodiment, by sensing a word line voltage, a condition or bit state of a memory cell in a cross-point array is determined, either directly by a sense amp comparing the accessed memory cell voltage with a reference voltage. Or less directly by first accessing the memory cell and storing a read voltage generated by forcing a read current through the cell and adjusting it up or down by 150 m V (or half the voltage difference resulting from changing the bit state), then writing the cell to AP state, and again accessing the memory cell with a read current and comparing the resulting voltage with the stored voltage adjusted 150 m V for example (or half the difference in voltage resulting from two different bit states. Memory die 292 also includes column decoder and control circuitry 210 whose input/outputs 206 are connected to respective bit lines of the memory structure 202. Although only a single block is shown for memory structure 202, a memory die can include multiple arrays or “tiles” that can be individually accessed. Column control circuitry 210 receives a group of N column address signals and one or more various control signals from System Control Logic 260, and typically may include such circuits as column decoders 212, column decoders and drivers 214, block select circuitry 216, as well as read/write circuitry, and I/O multiplexers.

System control logic 260 receives data and commands from a host system and provides output data and status to the host system. In other embodiments, system control logic 260 receives data and commands from a separate controller circuit and provides output data to that controller circuit, with the controller circuit communicating with the host system. Such controller system may implement an interface such as DDR, DIMM, CXL, PCIe and others. In another embodiment those data and commands are sent and received directly from the memory packages to the Host without a separate controller, and any controller needed is within each die or within a die added to a multi-chip memory package. In some embodiments, the system control logic 260 can include a state machine 262 that provides die-level control of memory operations. In some embodiments, state machine 262 controls a sequence of forming operations in the storage 104 as described herein. In one embodiment, the state machine 262 is programmable by software. In other embodiments, the state machine 262 does not use software and is completely implemented in hardware (e.g., electrical circuits). In another embodiment, the state machine 262 is replaced by a micro-controller or microprocessor. The system control logic 260 can also include a power control module 264 that controls the power, current source currents, and voltages supplied to the rows and columns of the memory structure 202 during memory operations and may include charge pumps and regulator circuit for creating regulating voltages, and on/off control of each for word line bit line selection of the memory cells. In some embodiments, the power control 264 includes one or more current sources. The current source(s) may be used to provide read and/or write currents. System control logic 260 includes storage 266, which may be used to store parameters for operating the memory structure 202. System control logic 260 also includes refresh logic 272 and wear leveling logic 274. Such system control logic may be commanded by the host 120 or memory controller 102 to refresh logic 272, which may load an on-chip stored row and column address (pointer) which may be incremented after refresh. Such address bit(s) may be selected only (to refresh the OTS). Or such address may be read, corrected by steering through ECC engine 269, and then stored in a “spare” location, which is also being incremented (so all codewords are periodically read, corrected, and relocated in the entire chip under control of wear leveling logic 274) to in effect wear level so use of each bit across the chip is more uniform. Such operation may be more directly controlled by the host of an external controller, for example a PCIe or CXL or DDRn controller located separately from the memory chip or on the memory die.

Commands and data are transferred between memory controller 102 and the memory die 292 via memory controller interface 268 (also referred to as a “communication interface”). Such interface may be PCIe, CXL, DDRn for example. Memory controller interface 268 is an electrical interface for communicating with memory controller 102. Examples of memory controller interface 268 also include a Toggle Mode Interface. Other I/O interfaces can also be used. For example, memory controller interface 268 may implement a Toggle Mode Interface that connects to the Toggle Mode interfaces of memory interface 228/258 for memory controller 102. In one embodiment, memory controller interface 268 includes a set of input and/or output (I/O) pins that connect to the controller 102. In another embodiment, the interface is JEDEC standard DDRn or LPDDRn, such as DDR5 or LPDDR5, or a subset thereof with smaller page and/or relaxed timing.

System control logic 260 located in a controller on the memory die in the memory packages may include Error Correction Code (ECC) engine 269. ECC engine 269 may be referred to as an on-die ECC engine, as it is on the same semiconductor die as the memory cells. That is, the on-die ECC engine 269 may be used to encode data and parity bits that are to be stored in the memory structure 202, and to decode the decoded data and correct errors. The encoded data may be referred to herein as a codeword or as an ECC codeword. ECC engine 269 may be used to perform a decoding algorithm and to perform error correction. Hence, the ECC engine 269 may decode the ECC codeword. In an embodiment, the ECC engine 269 is able to decode the data more rapidly by direct decoding without iteration. Having the ECC engine 269 on the same die as the memory cells allows for faster decoding. The ECC engine 269 can use a wide variety of decoding algorithms including, but not limited to, Reed Solomon, a Bose-Chaudhuri-Hocquenghem (BCH), and low-density parity check (LDPC).

In some embodiments, all of the elements of memory die 292, including the system control logic 260, can be formed as part of a single die. In other embodiments, some or all of the system control logic 260 can be formed on a different die; e.g., external controller chip.

In one embodiment, memory structure 202 comprises a three-dimensional memory array of non-volatile or volatile memory cells in which multiple memory levels are formed above a single substrate, such as a wafer. The memory structure may comprise any type of non-volatile or volatile memory that are monolithically formed in one or more physical levels of memory cells having an active area disposed above a silicon or silicon on insulator (or other type of) substrate. In another embodiment, memory structure 202 comprises a two-dimensional memory array of non-volatile memory cells.

The exact type of memory array architecture or memory cell included in memory structure 202 is not limited to the examples above. Many different types of memory array architectures or memory technologies can be used to form memory structure 202. No particular non-volatile memory technology is required for purposes of the newly claimed embodiments proposed herein. Other examples of suitable technologies for memory cells of the memory structure 202 include ReRAM memories (resistive random access memories), magnetoresistive memory (e.g., MRAM, Spin Transfer Torque MRAM, Spin Orbit Torque MRAM), FeRAM, phase change memory (e.g., PCM), and the like. Examples of suitable technologies for memory cell architectures of the memory structure 202 include two dimensional arrays, three dimensional arrays, cross-point arrays, stacked two dimensional arrays, vertical bit line arrays, and the like.

One example of a ReRAM or MRAM cross-point memory includes programmable resistance switching elements in series with an OTS selector arranged in cross-point arrays accessed by X lines and Y lines (e.g., word lines and bit lines). In another embodiment of cross-point is PCM in series with an OTS selector. In another embodiment, the memory cells may include conductive bridge memory elements. A conductive bridge memory element may also be referred to as a programmable metallization cell. A conductive bridge memory element may be used as a state change element based on the physical relocation of ions within a solid electrolyte. In some cases, a conductive bridge memory element may include two solid metal electrodes, one relatively inert (e.g., tungsten) and the other electrochemically active (e.g., silver or copper), with a thin film of the solid electrolyte between the two electrodes. As temperature increases, the mobility of the ions also increases causing the programming threshold for the conductive bridge memory cell to decrease. Thus, the conductive bridge memory element may have a wide range of programming thresholds over temperature.

Magnetoresistive random access memory (MRAM) stores data using magnetic storage elements. The elements are formed from two ferromagnetic layers, each of which can hold a magnetization, separated by a thin insulating layer. For a field-controlled MRAM, one of the two layers is a permanent magnet set to a particular polarity; the other layer's magnetization can be changed by applying an external field to store memory. Other types of MRAM cells are possible. A memory device may be built from a grid of MRAM cells or as SOT magneto resistive memory. MRAM based memory embodiments will be discussed in more detail below.

Phase change memory (PCM) exploits the unique behavior of chalcogenide glass. One embodiment uses a GeTe-Sb2Te3 super lattice to achieve non-thermal phase changes by simply changing the co-ordination state of the Germanium atoms with a laser pulse (or light pulse from another source). The memory cells are programmed by current pulses that can change the co-ordination of the PCM material or switch it between amorphous and crystalline states. Note that the use of “pulse” in this document does not require a square pulse but includes a (continuous or non-continuous) vibration or burst of sound, current, voltage, light, or other wave. And the current forced for a write can, for example, be driven rapidly to a peak value and then linearly ramped lower with, for example, a 500 ns edge rate. Such peak current force may be limited by a zoned voltage compliance that varies by position of the memory cell along the word line or bit line. In an embodiment, a phase change memory cell has a phase change memory element in series with a threshold switching selector such as an OTS.

A person of ordinary skill in the art will recognize that the technology described herein is not limited to a single specific memory structure, memory construction or material composition, but covers many relevant memory structures within the spirit and scope of the technology as described herein and as understood by one of ordinary skill in the art.

The elements of FIG. 2 can be grouped into two parts, the memory structure 202 and the peripheral circuitry, including all of the other elements. An important characteristic of a memory circuit is its capacity, which can be increased by increasing the area of the memory die 292 that is given over to the memory structure 202; however, this reduces the area of the memory die available for the peripheral circuitry or increases cost which is related to chip area. This can place quite severe restrictions on these peripheral elements. For example, the need to fit sense amplifier circuits within the available area can be a significant restriction on sense amplifier design architectures. With respect to the system control logic 260, reduced availability of area can limit the available functionalities that can be implemented on-chip. Consequently, a basic trade-off in the design of a memory die 292 is the amount of area to devote to the memory structure 202 and the amount of area to devote to the peripheral circuitry. Such tradeoffs may result in more IR drop from use of larger x-y arrays of memory between driving circuits on the word line and bit line, which in turn may benefit more from use of voltage limit and zoning of the voltage compliance by memory cell position along the word line and bit line.

Another area in which the memory structure 202 and the peripheral circuitry are often at odds is in the processing involved in forming these regions, since these regions often involve differing processing technologies and the trade-off in having differing technologies on a single die. For example, elements such as sense amplifier circuits, charge pumps, logic elements in a state machine, and other peripheral circuitry in system control logic 260 often employ PMOS devices. In some cases, the memory structure will be based on CMOS devices. Processing operations for manufacturing a CMOS die will differ in many aspects from the processing operations optimized for NMOS-only technologies.

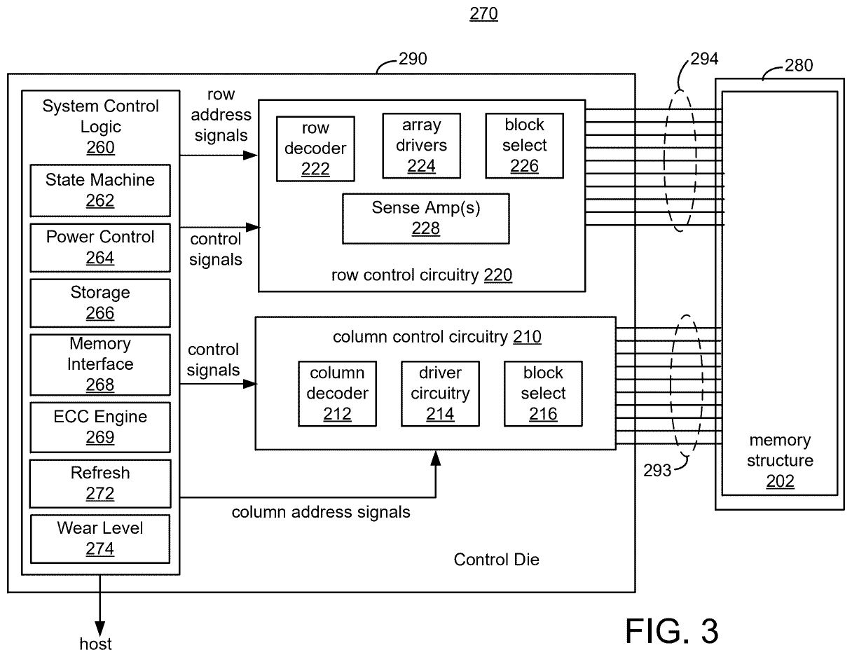

To improve upon these limitations, embodiments described below can separate the elements of FIG. 2 onto separately formed die that are then bonded together. FIG. 3 depicts an integrated memory assembly 270 having a memory structure die 280 and a control die 290. The memory structure 202 is formed on the memory structure die 280 and some or all of the peripheral circuitry elements, including one or more control circuits, are formed on the control die 290. For example, a memory structure die 280 can be formed of just the memory elements, such as the array of memory cells of MRAM memory, PCM memory, ReRAM memory, or other memory type. Some or all of the peripheral circuitry, even including elements such as decoders, current sources, and sense amplifiers, can then be moved on to the control die. This allows each of the semiconductor die to be optimized individually according to its technology. This allows more space for the peripheral elements, which can now incorporate additional capabilities that could not be readily incorporated were they restricted to the margins of the same die holding the memory cell array. The two die can then be bonded together in a bonded multi-die integrated memory assembly, with the array on the one die connected to the periphery elements on the other die. Although the following will focus on an integrated memory assembly of one memory die and one control die, other embodiments can use additional die, such as two memory die and one control die, for example.

As with memory die 292 of FIG. 2, the memory structure die 280 in FIG. 3 includes a memory structure 202 that can include multiple independently accessible arrays or “tiles.” System control logic 260, row control circuitry 220, and column control circuitry 210 are located in control die 290. In some embodiments, all or a portion of the column control circuitry 210 and all or a portion of the row control circuitry 220 are located on the memory structure die 280. In some embodiments, some of the circuitry in the system control logic 260 is located on the on the memory structure die 280.

FIG. 3 shows column control circuitry 210 on the control die 290 coupled to memory structure 202 on the memory structure die 280 through electrical paths 293. For example, electrical paths 293 may provide electrical connection between column decoder 212, column driver circuitry 214, and block select 216 and bit lines of memory structure 202. Electrical paths may extend from column control circuitry 210 in control die 290 through pads on control die 290 that are bonded to corresponding pads of the memory structure die 280, which are connected to bit lines of memory structure 202. Each bit line of memory structure 202 may have a corresponding electrical path in electrical paths 293, including a pair of bond pads, which connects to column control circuitry 210. Similarly, row control circuitry 220, including row decoder 222, row drivers 224, block select 226, and sense amplifiers 228 are coupled to memory structure 202 through electrical paths 294. Each of electrical path 294 may correspond to, for example, a word line. Additional electrical paths may also be provided between control die 290 and memory structure die 280.

For purposes of this document, the phrase “a control circuit” can include one or more of memory controller 102, local memory controller 164, processor 156, system control logic 260, column control circuitry 210, row control circuitry 220, host processor 122, a micro-controller, a state machine, and/or other control circuitry, or other analogous circuits that are used to control non-volatile memory. The control circuit can include hardware only or a combination of hardware and software (including firmware). For example, a controller programmed by firmware to perform the functions described herein is one example of a control circuit. A control circuit can include a processor, FPGA, ASIC, integrated circuit, or other type of circuit. Such control circuitry may include drivers such as direct drive via connection of a node through fully on transistors (gate to the power supply) driving to a fixed voltage such as a power supply. Such control circuitry may include a current source driver.

For purposes of this document, the term “apparatus” can include, but is not limited to, one or more of memory system 100, local memory 140, the combination of local memory controller 164 and/or memory controller 102 and local memory 140, storage 104, memory die 292, integrated memory assembly 270, and/or control die 290.

In the following discussion, the memory structure 202 of FIGS. 2 and 3 will be discussed in the context of a cross-point architecture. In a cross-point architecture, a first set of conductive lines or wires, such as word lines, run in a first direction relative to the underlying substrate and a second set of conductive lines or wires, such a bit lines, run in a second direction relative to the underlying substrate. The memory cells are sited at the intersection of the word lines and bit lines. The memory cells at these cross-points can be formed according to any of a number of technologies, including those described above. The following discussion will mainly focus on embodiments based on a cross-point architecture having memory cells using a threshold switching selector such as Ovonic Threshold Switch (OTS). However, embodiments are not limited to a cross-point architecture having memory cells using an OTS. For example, the cross-point memory array may have memory cells of other technologies such as ReRam, PCM (Phase Change Memory), or FeRam.

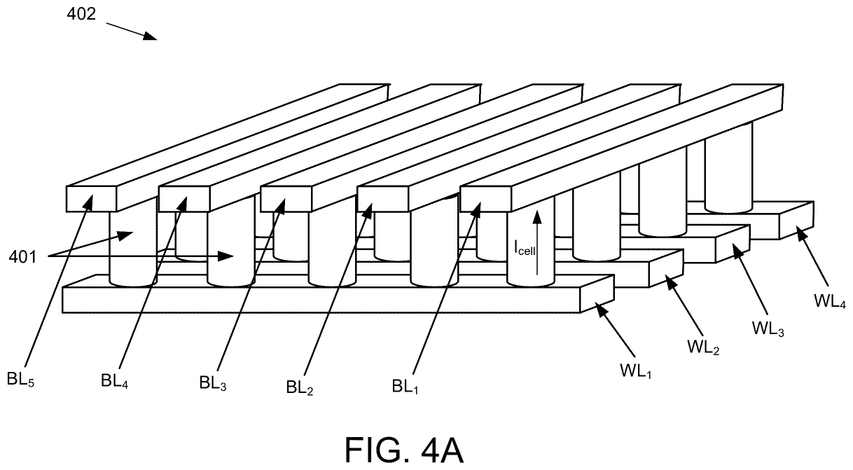

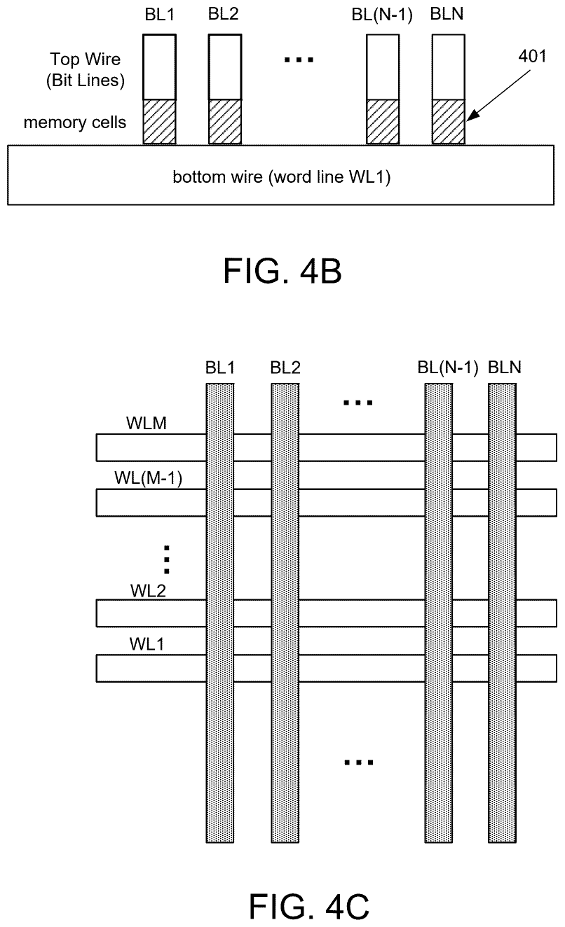

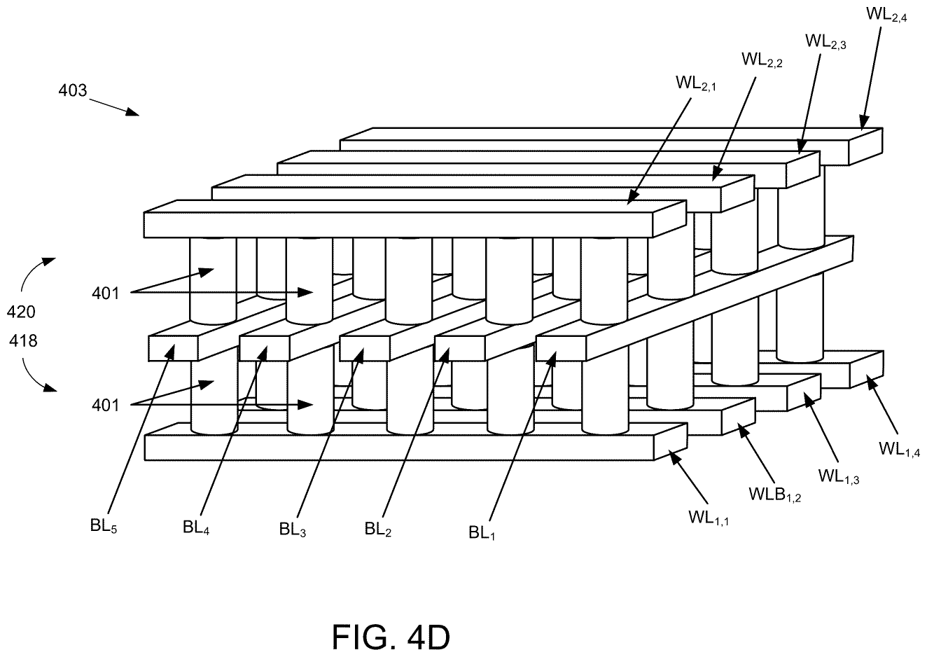

FIG. 4A depicts one embodiment of a portion of a memory array 402 that forms a cross-point architecture in an oblique view. Memory array 402 of FIG. 4A is one example of an implementation for memory structure 202 in FIG. 2 or 3, where a memory die 292 or memory structure die 280 can include multiple such memory arrays 402. The memory array 402 may be included in local memory 140 or host memory 124. The bit lines BL₁-BL₅ are arranged in a first direction (represented as running into the page) relative to an underlying substrate (not shown) of the die and the word lines WL₁-WL₅ are arranged in a second direction perpendicular to the first direction, or diagonal to provide intersections where memory cells are interconnected between WLs and BLs. FIG. 4A is an example of a horizontal cross-point structure in which word lines WL₁-WL₅ and BL₁-BL₅ both run in a horizontal direction relative to the substrate, while the memory cells, two of which are indicated at 401, are oriented so that the current through a memory cell (such as shown at I_{cell}) runs in the vertical direction. In a memory array with additional layers of memory cells, such as discussed below with respect to FIG. 4D, there would be corresponding additional layers of bit lines and word lines. One pattern, for example, would be from the bottom layer: WL, memory cell, BL, memory cell, WL, WL, memory cell, BL memory cell, WL.

As depicted in FIG. 4A, memory array 402 includes a plurality of memory cells 401. The memory cells 401 may include re-writeable memory elements, such as can be implemented using ReRAM, MRAM, PCM, or other material with a programmable resistance. In an embodiment, the memory cells 401 are selector only memory (SOM). The memory cells 401 may be referred to herein as programmable resistance memory cells. One type of programmable resistance memory cell is referred to as an MRAM cell, which is a memory cell that includes a MRAM memory element. The memory cells 401 may also include threshold switching selectors as an additional series element within the memory cells 401, such as can be implemented using an Ovonic Threshold Switch (OTS), Volatile Conductive Bridge (VCB), Metal-Insulator-Metal (MIM), or other material that provides a highly non-linear dependence of current or resistance for varying select voltage. The current in the memory cells of the first memory level is shown as flowing upward as indicated by arrow I_{cell}, but current can flow in either direction to either read or write the memory cell bit state, as is discussed in more detail in the following.

FIGS. 4B and 4C respectively present side and top views of the cross-point structure in FIG. 4A. The sideview of FIG. 4B shows one bottom wire, or word line, WL₁ and the top wires, or bit lines, BL₁-BLₙ. At the cross-point between each top wire and bottom wire is a memory cell 401. The memory cell 401 may be a SOM, MRAM, ReRAM, or other technologies. FIG. 4C is a top view illustrating the cross-point structure for M bottom wires WL₁-WL_{M} and N top wires BL₁-BL_{N}. In a binary embodiment, the memory cell at each cross-point can be programmed into one of two resistance states: high and low. More details on embodiments for a memory cell design and techniques for their reading are given below. In some embodiments, sets of these wires are arrayed continuously as a “tile,” and such tiles may be paired adjacently in the Word Line (WL) direction and orthogonally in the Bit Line direction to create a module. Such a module may be composed of 2×2 tiles to form a four tile combination wherein the WL drivers between the tiles is “center driven” between the tiles with the WL running continuously over the transistor driver at the approximate center of the line. Similarly, BL drivers may be located between the pair of tiles paired in the BL direction to be center driven, whereby the transistor driver and its area is shared between a pair of tiles. Vias of copper or other types of low resistance may decode and connect the transistor driver/selects to the WL or BL. In addition to the memory element in the memory cell between WL and BL may also be included a series select element such as an OTS.

The cross-point array of FIG. 4A illustrates an embodiment with one layer of word lines and bits lines, with the memory cells sited at the intersection of the two sets of conducting lines. To increase the storage density of a memory die, multiple layers of such memory cells and conductive lines can be formed. A two-layer example is illustrated in FIG. 4D.

FIG. 4D depicts an embodiment of a portion of a two-level memory array that forms a cross-point architecture in an oblique view. As in FIG. 4A, FIG. 4D shows a first layer 418 of memory cells 401 of a memory array 403 connected at the cross-points of the first layer of word lines WL_{1,1}-WL_{1,4} and bit lines BL₁-BL₅ above. Memory array 403 may be included in memory structure 202 of FIG. 2 or 3. A second layer 420 of memory cells is formed above the bit lines BL₁-BL₅ and between these bit lines and a second set of word lines WL_{2,1}-WL_{2,4}. In effect the BLs are shared. In the alternative a second layer may include another deck of BL above the BL shown and below the 2^{nd} deck of WL. Although FIG. 4D shows two layers, 418 and 420, of memory cells, the structure can be extended upward through additional alternating layers of word lines and bit lines in a similar pattern. Depending on the embodiment, the word lines and bit lines of the array of FIG. 4D can be biased for read or program operations such that current in each layer flows from the word line layer to the bit line layer or the other way around. The two layers can be structured to have current flow in the same direction in each layer for a given operation or to have current flow in the opposite directions by driver selection in the positive or negative direction. The memory cell may be placed in the same orientation within the first and second layers enabling use of current in oppositive directions by layer to read or write. Or the memory cell placed in a reversed or flipped direction when placed between the BL and WL in the second layer (enabling use of current in the same direction as is used to read or write in memory cells within the first layer. As will be apparent to someone reasonably skilled in the art, the two layers can be extended to three or more layers.

The use of a cross-point architecture allows for arrays with a small footprint and several such arrays can be formed on a single die. The memory cells formed at each cross-point can be a resistive type of memory cell, where data values are encoded as different resistance levels, either two levels such as with MRAM or into two or more levels for other memory element technologies such as PCM. Depending on the embodiment, the memory cells can be binary valued, having either a low resistance state or a high resistance state, or multi-level cells (MLCs) that can have additional resistance intermediate to the low resistance state and high resistance state. The cross-point arrays described here can be used in the memory die 292 of FIG. 2, the local memory 140 in FIG. 1, and/or the host memory 124 in FIG. 1, or in any other configuration where additional memory is useful. Resistive type memory cells can be formed according to many of the technologies mentioned above, such as ReRAM, PCM, FeRAM, or MRAM.

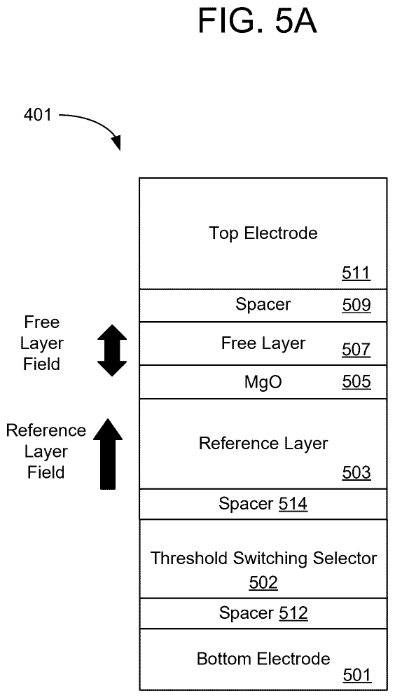

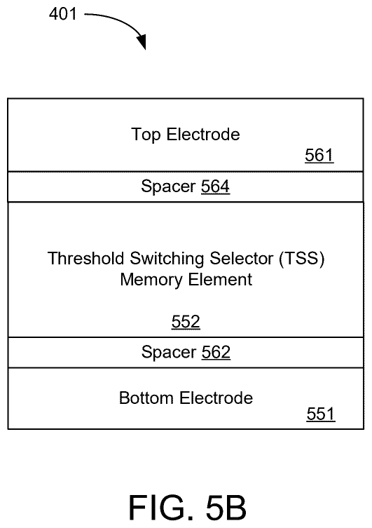

FIG. 5A illustrates the structure of an embodiment for an MRAM cell. The MRAM cell may be used as the programmable resistance memory cell 401 in, for example, FIGS. 4A-4D. The MRAM cell includes a bottom electrode 501, spacer 512, a threshold switching selector 502, spacer 514, a pair of magnetic layers (reference layer 503 and free layer 507) separated by a separation or tunneling layer of, in this example, magnesium oxide (MgO) 505, and then a top electrode 511 separated from the free layer 507 by a spacer 509. The combination of magnetic layers 503, 507 and tunneling layer 505 may be referred to as a magnetic tunnel junction (MTJ). The spacer 509 can consist of an MgO capping layer in contact with the free layer 507. The spacer 509 can also contain additional metal layers. In another embodiment, the locations of the reference layer 503 and free layer 507 are switched, with the reference layer 503 on top of MgO 505, and the free layer 507 below MgO 505. In another embodiment, the location of the threshold switching selector 502 is between the free layer 507 and the top electrode 511.

In some embodiments, the bottom electrode 501 is a word line and the top electrode 511 is a bit line. In other embodiments, the bottom electrode 501 is a bit line and the top electrode 511 is a word line. The state of the memory cell is based on the relative orientation of the magnetizations of the reference layer 503 and the free layer 507: if the two layers are magnetized in the same direction, the memory cell will be in a parallel (P) low resistance state (LRS); and if they have the opposite orientation, the memory cell will be in an anti-parallel (AP) high resistance state (HRS). An MLC embodiment would include additional intermediate states. The orientation of the reference layer 503 is fixed and, in the example of FIG. 5A, is oriented upward. Reference layer 503 is also known as a fixed layer or pinned layer. The reference layer 503 can be composed of multiple ferromagnetic layers coupled anti-ferromagnetically in a structure commonly referred to a synthetic anti-ferromagnet or SAF for short.

Data is written to an MRAM memory cell by programming the free layer 507 to either have the same orientation or opposite orientation of the reference layer 503. An array of MRAM memory cells may be placed in an initial, or erased, state by setting all of the MRAM memory cells to be in the low resistance state in which all of their free layers have a magnetic field orientation that is the same as their reference layers. Each of the memory cells is then selectively programmed (also referred to as “written”) by placing its free layer 507 to be in the high resistance state by reversing the magnetic field to be opposite that of the reference layer 503. The reference layer 503 is formed so that it will maintain its orientation when programming the free layer 507. The reference layer 503 can have a more complicated design that includes synthetic anti-ferromagnetic layers and additional reference layers. For simplicity, the figures and discussion omit these additional layers and focus only on the fixed magnetic layer primarily responsible for tunneling magnetoresistance in the cell.

The threshold switching selector 502 has a high resistance (in an off or non-conductive state) until it is biased to a voltage higher than its threshold voltage or current above its threshold current, and until its voltage bias falls below Vhold (also known as “Voffset”) or current below Ihold. After Vth is exceeded and while Vhold is exceeded across the switching selector, the switching selector has a low resistance (in an on or conductive state). The threshold switching selector remains on until its current is lowered below a holding current Ihold, or the voltage is lowered below a holding voltage, Vhold. When this occurs, the threshold switching selector returns to the off (higher) resistance state. Accordingly, to program a memory cell at a cross-point, a voltage or current is applied which is sufficient to turn on the associated threshold switching selector and set or reset the memory cell; and to read a memory cell, the threshold switching selector similarly is activated by being turned on before the resistance state of the memory cell is determined. One set of examples for a threshold switching selector is an ovonic threshold switching material of an Ovonic Threshold Switch (OTS). Example threshold switching materials include Ge—Se, Ge—Se—N, Ge—Se—As, Ge—Se—Sb—N, GeSe, GeTe₆, Si—Te, Zn—Te, C—Te, B—Te, Ge—As—Te—Si—N, Ge—As—Se—Te—Si and Ge—Se—As—Te, with atomic percentages ranging from a few percent to more than 90 percent for each element. In an embodiment, the threshold switching selector is a two terminal device. The threshold switching selector 502 can also contain additional conducting layers on the interface with the reference layer 503. For example, spacer 514 is depicted between switching selector 502 and reference layer 503. The spacer layer 514 on the interface with reference layer 503 can be a single conducting layer or composed of multiple conducting layers. The threshold switching selector 502 can also contain additional conducting layers on the interface with the bottom electrode 501. For example, spacer 512 is depicted between switching selector 502 and reference layer 503. The spacer layer 512 on the interface with bottom electrode 501 can be a single conducting layer or composed of multiple conducting layers. Examples of conducting layers adjacent to the OTS include carbon, carbon nitride, carbon silicide, carbon tungsten, titanium, titanium nitride, tungsten, tungsten nitride, tantalum, tantalum nitride, and others. Threshold voltage switches have a Threshold Voltage (Vth) above which the resistance of the device changes substantially from insulating, or quasi insulating, to conducting.

In an embodiment, a current-force approach is used to access the MRAM cell. The current-force approach may be used to read or write the MRAM cell. In an embodiment, current-force approach is used to lower the threshold voltage of a threshold switching selector in a programmable resistance memory cell. In the current-force approach, an access current (e.g., I_{read}, I_{write}, I_{drive}) is driven through the bottom electrode 501 by a current driver. The current will be provided by a transistor or resistor based current source. In an embodiment, the current driver may be a part of the address selected row driver circuitry (e.g., array drivers 224) for the electrode 501. However, alternatively the current driver may be a part of the address selected column driver circuitry (e.g., driver circuitry 214) for the electrode 501. A voltage (e.g., V_{select}) is provided to the top electrode 511. Herein, the terms “read current” (I_{read}) and “write current” (I_{write}) will be used in connection with access currents that are driven through MRAM cells (or other programmable resistance cells). The write current may change the state of the MRAM cell. As an example, a write current of about 30 μA for 50 ns may be used for an MRAM cell with a Critical Dimension (CD) of approximately 20 nanometers with RA 10 Ωμm 2 to switch the MRAM state from the P-state to the AP-state. Read currents may be about half the write current if applied for a limited time, such as <20 ns. A write current that flows in one direction through the MRAM cell will change an AP-state MRAM cell to the P-state. A write current that flows in the other direction, such as in the read direction, through the MRAM cell will change a P-state MRAM cell from the P-state to the AP-state. In general until the cell state is determined or a voltage level is captured and stored that correlates to the memory cell state, a read current will preferably be set low enough and the read duration short enough so as not to change the state of an MRAM cell from the P-state to the AP-state or from the AP-state to the P-state during read. Typically the write current required to switch the MRAM state from the P-state to the AP-state is larger in absolute magnitude than the write current required to switch the MRAM state from the AP-state to the P-state, so this may be a preferred direction to read for offering my margin against a state change before the bit state is correctly sensed. Current magnitudes may be adjusted accordingly by write direction, or the current used for P to AP if a single magnitude is used.

In some embodiments, a read current may be applied in a P2AP direction or, alternatively, in an AP2P direction. In some embodiments, the MRAM cell is read by performing an SRR (self-referenced-read). In one embodiment, the SRR has a first read (Read1 in the P2AP direction), a first write (Write 1 to the AP-state), and a second read (Read2 in the P2AP direction). Then the original state of the cell may be restored by a second write (Write_Back to the P-state for bits initially in the P-state). Or in another embodiment, the SRR read current and destructive write currents are both reversed; for example when addressing the second layer with a memory cell oriented the same as in the first layer.

In an embodiment, the voltage level of the memory cell due to Read1 in the P2AP direction is sensed and stored, for example on a capacitor; or by conversion to digital bits by an Analog to Digital converter and the bits stored in memory, for example in SRAM until after use in Read2. The state stored on a capacitor can be adjusted, for example, 150 mv positive or negative by forcing a voltage on one terminal of a capacitor connected to the storage capacitor. Or the digital stored level can be adjusted by digitally adding or subtracting 150 mV to the stored bits. The 150 mV can be adjusted to be dependent on the typical bit resistance. For example, if the bit low resistance state is 25K ohms and the high resistance 50K ohms, the difference is 25K ohms. If the read current is 15 μA, the difference voltage between the states if 25K ohms×15 μA=375 mV, making a choice of 15 0 mV acceptable but perhaps suggesting 187.5 mV may be more optimum, for example.

Although the foregoing describes reads in the P2AP direction and destructive writes to the AP-state (with write back after SRR to the P-state), in an alternative embodiment the first SRR has a first read (Read1 in the AP2P direction), a destructive write (Write 1) to the P-state and a second read (Read2) in the AP2P direction.

In one embodiment, the MRAM cell is read by applying, for example, approximately OV to the top electrode 511 by turning on a transistor connected between 511 and a power supply, while driving a current of, for example, 15 micro-Amperes (μA) through the bottom electrode 501. This read current may flow from the bottom electrode 501 to the top electrode 511. Note that the read may be Read1 or Read2 in the P2AP direction. P2AP means current flows in the direction that would write the bit from P to AP or AP to AP. In some embodiments, data is written to the MRAM cell using a bipolar write operation. In one embodiment, the MRAM cell is written from the AP-state to the P-state by applying, for example, 3V to the top electrode 511, while driving a write current of, for example, −30 μA through the bottom electrode 501. This write current will flow from the top electrode 511 to the bottom electrode 501. In one embodiment, the MRAM cell is written from the P-state to the AP-state by applying, for example, OV to the top electrode 511, while driving a current of, for example, 30 μA through the bottom electrode 501. This write current will flow from electrode 501 to the electrode 511.

As an alternative to the approach in FIG. 5A, the select voltage can be applied to the bottom electrode 501 with the access current applied through the top electrode 511. In one such embodiment, the MRAM cell is read by applying, for example, 3V to the bottom electrode 501, while driving a read current of, for example, −15 μA through the top electrode 511. This read current may flow from the bottom electrode 501 to the top electrode 511.

In one embodiment, the MRAM cell is written from the AP-state to the P-state by applying, for example, −3V to the bottom electrode 501, while driving a write current of, for example, 30 μA through the top electrode 511. The electron current will flow from the bottom electrode 501 to the top electrode 511. In one embodiment, the MRAM cell is written from the P-state to the AP-state by applying, for example, OV to the bottom electrode 501, while driving a current of, for example, −30 μA through the top electrode 511. The electron current will flow from the top electrode 511 to the bottom electrode 501. The direction of the current polarity to switch the magnetization of the bit into the P or AP state can vary based on reference layer design and the location of the reference layer with respect to the free layer.

Some biasing techniques may result in voltage across non-selected memory cells of the array, which can induce “leakage” currents in non-selected memory cells. Although this wasted power consumption can be mitigated to some degree by designing the memory cells to have relatively high resistance levels for both high and low resistance states when WL or BL is address unselected, this overhead leakage will still result in increased current and power consumption as well as placing additional design constraints on the design of the memory cells and the array due to lack of read and write margin. One approach to reduce this unwanted current leakage is to place a selector element in series with each MRAM or other resistive (e.g., ReRAM, PCM) memory cell. For example, a select transistor can be placed in series with each resistive memory cell element in FIGS. 4A-4D so that the memory cells 401 is now a composite of a select transistor and a programmable resistance. Such an architecture may be referred to as 1T1R. Use of a select transistor, however, requires the introduction of additional control lines and cell area to be able to turn on the corresponding transistor of a selected memory cell. Additionally, transistors will often not scale in the same manner as the resistive memory element write current, so that as memory arrays move to smaller sizes the use of transistor based selectors can be a limiting factor in reducing cost, for example. An alternate approach to select transistors is the use of a two-terminal threshold switching selector (e.g., threshold switching selector 502) in series with the programmable resistive element. A two-terminal threshold switching selector does not require the aforementioned additional control lines and additional cell area to be able to turn on the corresponding select transistor of a selected memory cell. However, as will be discussed in more detail below, there may still be some leakage current even when a two-terminal threshold switching selector is in the off state. Embodiments of a memory system control the slope of a trailing edge of a pulse applied to a selected memory cell to mitigate the effects of leakage currents in memory cells having two-terminal threshold switching selectors.

FIG. 5B illustrates the structure of an embodiment for a selector-only memory (SOM) cell. The SOM cell may be used as the programmable resistance memory cell 401 in, for example, FIGS. 4A-4D. The SOM cell includes a bottom electrode 551, spacer 562, a threshold switching selector (TSS) memory element 552, spacer 564, and a top electrode 561. In some embodiments, the bottom electrode 551 is a word line and the top electrode 561 is a bit line. In other embodiments, the bottom electrode 551 is a bit line and the top electrode 561 is a word line. The state of the memory cell is based on the state of the TSS memory element 552. Embodiments of a memory system control the slope of a trailing edge of a pulse applied to a selected SOM cell to mitigate the effects of leakage currents in SOM cells.

Data is written to an SOM memory cell by programming the TSS memory element 552 with a program (or write) signal (e.g., program current, program voltage) having a desired polarity. In one embodiment, the SOM memory cell is programmed to a first state (WO) using a first polarity program signal and to a second state (W1) using a second polarity program signal. The SOM memory cell may be read using a read signal (e.g., read current, read voltage). The polarity of the read signal relative to the polarity of the program signal may impact the Vth of the SOM cell. In an embodiment, a read signal having the same polarity as the program signal results in a lower Vth than a read signal having the opposite polarity as the program signal. Typically, the memory system will choose a polarity for the read signal and then be consistent with that polarity of read signal when determining the state of the SOM cell. Therefore, the polarity of the program signal will, in effect, result in a higher/lower Vth when read with the chosen polarity read signal.

The threshold switching selector 552 may also serve as a selector to select the memory cell for a memory operation. The threshold switching selector 552 has a high resistance (in an off or non-conductive state) until it is biased to a voltage higher than its threshold voltage (Vth) or current above its threshold current, and until its voltage bias falls below Vhold (also known as “Voffset”) or current below Ihold. After the Vth is exceeded and while Vhold is exceeded across the switching selector, the switching selector has a low resistance (in an on or conductive state). The threshold switching selector remains on until its current is lowered below a holding current Ihold, or the voltage is lowered below a holding voltage, Vhold. When this occurs, the threshold switching selector returns to the off (higher) resistance state. Accordingly, to select a memory cell at a cross-point, a voltage or current is applied which is sufficient to turn on the associated threshold switching selector. One set of examples for a threshold switching selector is an ovonic threshold switching material of an Ovonic Threshold Switch (OTS). Example threshold switching materials include Ge—Se, Ge—Se—N, Ge—Se—As, Ge—Se—Sb—N, Ge58Se42, GeTe6, Si—Te, Zn—Te, C—Te, B—Te, Ge—As—Te—Si—N, Ge—As—Se—Te—Si and Ge—Se—As—Te, with atomic percentages ranging from a few percent to more than 90 percent for each element. In an embodiment, the threshold switching selector is a two terminal device. The threshold switching selector 552 can also contain additional conducting layers. For example, spacer 564 is depicted between switching selector 552 and top electrode 561. The spacer layer 564 can be a single conducting layer or composed of multiple conducting layers. The threshold switching selector 552 can also contain additional conducting layers on the interface with the bottom electrode 551. For example, spacer 562 is depicted between switching selector 552 and bottom electrode 551. The spacer layer 562 on the interface with bottom electrode 551 can be a single conducting layer or composed of multiple conducting layers. Examples of conducting layers adjacent to the OTS include carbon, carbon nitride, carbon silicide, carbon tungsten, titanium, titanium nitride, tungsten, tungsten nitride, tantalum, tantalum nitride, and others. Threshold voltage switches have a Threshold Voltage (Vth) above which the resistance of the device changes substantially from insulating, or quasi insulating, to conducting.

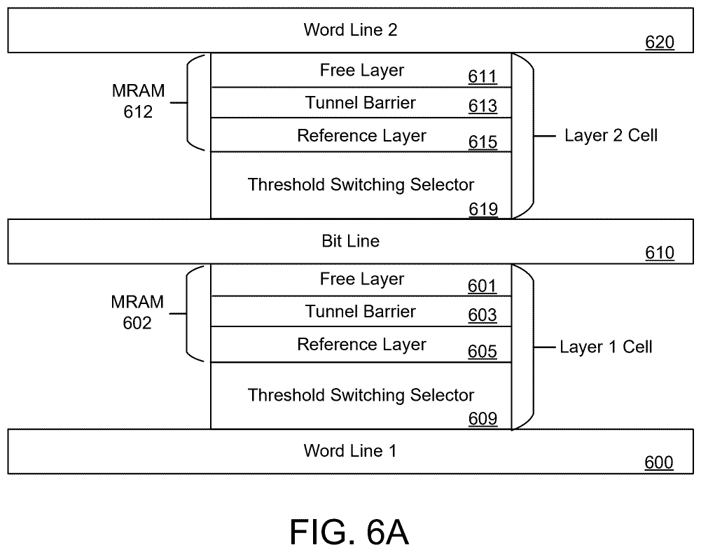

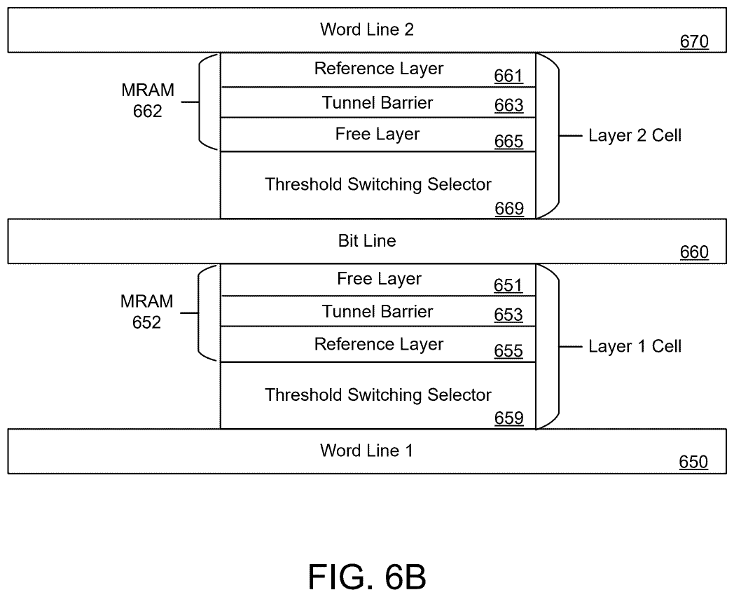

FIGS. 6A and 6B illustrate embodiments for the incorporation of threshold switching selectors into an MRAM memory array having a cross-point architecture. The examples of FIGS. 6A and 6B show two MRAM cells (Layer 1 Cell, Layer 2 Cell) in a two layer cross-point array, such as shown in FIG. 4D, but in a side view. Keeping the orientation of the MRAM layers the same in the Layer 1 Cell and the Layer 2 Cell, as depicted in FIG. 6A, allows the fabrication process to be the same for each layer. Whereas 6B has the memory cell inverted which allows the drive circuitry to work the same; e.g., BL goes Low to Read P2AP for each layer. FIGS. 6A and 6B show a lower first conducting line of word line 1 600, an upper first conducting line of word line 2 620, and an intermediate second conducting line of bit line 610. In these figures, all of these lines are shown running left to right across the page for ease of presentation, but in a cross-point array they would be more accurately represented as in the oblique view of FIG. 4D where the word lines, or first conducting lines or wires, run in one direction parallel to the surface of the underlying substrate and the bit lines, or second conducting lines or wires, run in a second direction parallel to the surface to the substrate that is largely orthogonal to the first direction. The MRAM memory cells are also represented in a simplified form, showing only the reference layer, free layer, and the intermediate tunnel barrier, but in an actual implementation would typically include the additional structure described above with respect to FIG. 5.

An MRAM element 602 including free layer 601, tunnel barrier 603, and reference layer 605 is formed above the threshold switching selector 609, where this series combination of the MRAM element 602 and the threshold switching selector 609 together form the layer 1 cell between the bit line 610 and word line 1 600. The series combination of the MRAM element 602 and the threshold switching selector 609 operate largely as described above when the threshold switching selector 609 is turned on. Initially, though, the threshold switching selector 609 needs to be turned on by applying a voltage above the threshold voltage Vth of the threshold switching selector 609, and then the biasing current or voltage needs to be maintained high enough above the holding current or holding voltage of the threshold switching selector 609 so that it stays on during the subsequent read or write operation.

On the second layer, an MRAM element 612 includes free layer 611, tunnel barrier 613, and reference layer 615 is formed above the threshold switching selector 619, with the series combination of the MRAM element 612 and the threshold switching selector 619 together forming the layer 2 cell between the bit line 610 and word line 2 620. The layer 2 cell will operate as for the layer 1 cell, although the lower conductor now corresponds to a bit line 610 and the upper conductor is now a word line, word line 2 620. Additional paired layers may similarly share another bit line between them, having a pattern of WL1, BL1, WL2; WL3, BL2, WL4; or have separate bit lines in a pattern such as WL1, BL1, WL2, BL2. Or separate bit lines in a pattern of WL1, BL1, BL2, WL2. Note that each MRAM element 602, 612 may also be referred to as an MTJ.

In the embodiment of FIG. 6A, the threshold switching selector 609/619 is formed below the MRAM element 602/612, but in alternate embodiments the threshold switching selector can be formed above the MRAM element for one or both layers. The MRAM memory cell is directional. In FIG. 6A, the MRAM elements 602 and 612 have the same orientation, with the free layer 601/611 above (relative to the unshown substrate) the reference layer 605/615. Forming the layers between the conductive lines with the same structure can have a number of advantages, particularly with respect to processing as each of the two layers, as well as subsequent layers in embodiments with more layers, can be formed according to the same processing sequence.

FIG. 6B illustrates an alternate embodiment that is arranged similarly to that of FIG. 6A, except that in the layer 2 cell the locations of the reference layer and free layer are reversed. More specifically, between word line 1 650 and bit line 660, as in FIG. 6A the layer cell 1 includes an MRAM element 1 having a free layer 651 formed over tunnel barrier 653, that is turn formed over the reference layer 655, with the MRAM element 652 formed over the threshold switching selector 659. The second layer of the embodiment of FIG. 6B again has an MRAM element 662 formed over a threshold switching selector 669 between the bit line 660 and word line 2 670, but, relative to FIG. 6A, with the MRAM element 662 inverted, having the reference layer 661 now formed above the tunnel barrier 663 and the free layer 665 now under the tunnel barrier 663. Alternatively, the configuration of MRAM element 662 may be used for the Layer 1 cell and the configuration of MRAM cell 652 may be used for the Layer 2 cell.

Although the embodiment of FIG. 6B requires a different processing sequence for the forming of layers, in some embodiments it can have advantages. In particular, the directionality of the MRAM structure can make the embodiment of FIG. 6B attractive since when writing or reading in the same direction (with respect to the reference and free layers) the bit line will be biased the same for both the lower layer and the upper layer, and both word lines will be biased the same. For example, if both layer 1 and layer 2 memory cells are sensed in the P2AP direction (with respect to the reference and free layers), the bit line layer 660 will be biased such as in the P2AP direction, the bit line 660 is biased low (e.g., OV) for both the upper and lower cell, with word line 1 650 and word line 2 670 both biased to a higher voltage level. Similarly, with respect to writing, for writing to the high resistance AP state the bit line 660 is biased low (e.g., OV) for both the upper and lower cell, with word line 1 650 and word line 2 670 both biased to a higher voltage level.

To either read data from or write data to an MRAM memory cell involves passing a current through the memory cell. In embodiments where a threshold switching selector is placed in series with the MRAM element, before the current can pass through the MRAM element the threshold switching selector may be turned on by applying a sufficient voltage across and current through the series combination of the threshold switching selector and the MRAM element.

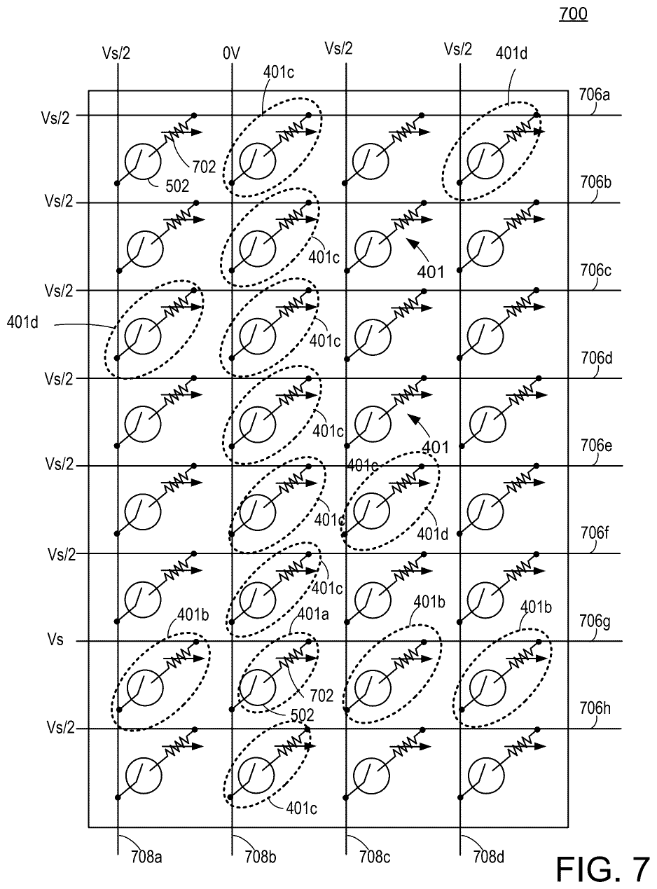

FIG. 7 depicts an embodiment of a memory array 700 having a cross-point architecture. The memory array 700 may be included in memory structure 202 of FIG. 2 or 3. The array 700 has a set of first conductive lines 706a-706h and a set of second conductive lines 708a-708d. In one embodiment, the set of first conductive lines 706a-706h are word lines and the set of second conductive lines 708a-708b are bit lines. For ease of discussion, the set of first conductive lines 706a-706h may be referred to as word lines and the set of second conductive lines 708a-708b may be referred to as bit lines. However, the set of first conductive lines 706a-706h could be bit lines and the set of second conductive lines 708a 708b could be word lines.

The memory array 700 has a number of programmable resistance memory cells 401. Each memory cell 401 is connected between one of the first conductive lines 706 and one of the second conductive lines 708 (e.g., at the cross point of one of the first conductive lines 706 and one of the second conductive lines 708). Each memory cell has a programmable resistance memory element 702 in series with a threshold switching selector 502. In one embodiment, the programmable resistance memory element includes a magnetoresistive random access memory (MRAM) element. The threshold switching selector 502 is configured to become conductive with lower resistance in response to application of a voltage level exceeding a threshold voltage of the threshold switching selector 502, and remains conductive with lower resistance until the current through the switching selector 502 is reduced below the selector holding current, Ihold. The threshold switching selector 502 may be a two terminal device. In an embodiment, the threshold switching selector 502 comprises an OTS.

Embodiments are disclosed herein for controlling the shape of the trailing edge of a pulse applied to the selected word line while a select voltage is applied to the selected bit line. Alternatively, the pulse could be applied to the selected bit line while a select voltage is applied to the selected word line, in which case the shape of the trailing edge of a pulse applied to the selected bit line may be performed.

For purpose of discussion, memory cell 401a is being selected for memory operation which could be a write or a read. Selected memory cell 401a is at the cross-point of selected word line 706g and selected bit line 708b. A selected memory cell means a memory cell that is selected for a memory operation such as read or write. A selected memory cell is connected between a selected word line and a selected bit line. To access a selected memory cell 401, a select voltage such as near ground is provided to the selected bit line (e.g., bit line 708b) and a select voltage (Vs) is applied to a selected word line (e.g., word line 706g). Note that Vs might be a program voltage or a read voltage. A selected word line means that the word line is connected to at least one selected memory cell. Alternatively, the memory cell could be selected by applying the for select voltage (Vs) to the selected bit line while applying a select voltage to the selected word line. More generally, the select voltage (Vs) is applied across the selected memory cell. For example, an alternative is to apply +Vs/2 to the selected word line and −Vs/2 to the selected bit line, with OV applied to unselected word lines and unselected bit lines.

In one approach word lines that are not connected to the selected memory cell may be driven by a voltage that is approximately one-half the magnitude of the select voltage. As depicted in FIG. 7, word lines 706a, 706b, 706c, 706d, 706e, 706f, and 706h each have what is referred to as a half-select voltage (Vs/2) applied thereto. The half-select voltage (Vs/2) has approximately one-half the magnitude of the select voltage (Vs). The term “half-selected memory cell,” as defined herein, is a memory cell that has approximately ½ of the voltage across it compared to the selected memory cell.

In one approach bit lines that are not connected to the selected memory cell may be driven by a voltage that is approximately one-half the magnitude of the select voltage. As depicted in FIG. 7, bit lines 708a, 708c, and 708d each have what is referred to as a half-select voltage (Vs/2) applied thereto. Alternative biasing schemes to the unselected word lines and unselected bit lines may be used if, for example, Vs/2 is applied to the selected word line and −Vs/2 is applied to the selected bit line. As noted above, the half-select voltage (Vs/2) has approximately one-half the magnitude of the select voltage (Vs).

Unselected memory cells connected to the selected word line are what is referred to herein as half-selected memory cells. The voltage across a half-selected memory cell is approximately half of the voltage across a selected memory cell. The half-selected memory cells 401b connected to the selected word line each have Vs applied to the selected word line and Vs/2 applied to their respective bit lines. Therefore, half-selected memory cells 401b each have Vs/2 applied across the memory cell.

Unselected memory cells connected to the selected bit line are also what is referred to herein as half-selected memory cells. The voltage across these half-selected memory cell is approximately half of the voltage across the selected memory cell. The half-selected memory cells 401c connected to the selected bit line each have OV applied to the selected bit line and Vs/2 applied to their respective word lines. Therefore, half-selected memory cells 401c each have Vs/2 applied across the memory cell.

Memory cells connected to both an unselected word line and an unselected bit line are fully unselected by which it is meant they have approximately OV across the memory cell. A few of the fully unselected memory cells 401d are pointed out in FIG. 7. In this example, each fully unselected memory cell 401d has Vs/2 applied to its word line and Vs/2 applied to its bit line. The threshold switching selector 502 of fully unselected memory cells 401d will not turn on even if the threshold voltage of the threshold switching selector 502 is somewhat lower than a target Vth range.

Vs/2 should be lower than the Vth of the half-selected memory cells; therefore, the threshold switching selector in the half-selected memory cells should not turn on. However, there may still be a relatively low current through such half-selected memory cells. The current through fully unselected memory cells should be much lower than for the half-selected memory cells due to the very small (if any) voltage across the fully unselected memory cells. The collective currents in un-selected memory cells in the cross-point array is referred to as a leakage current. The leakage current may increase with wear to the memory cells. Specifically, the leakage current may increase with wear to the threshold switching selectors. This wear may be a function of memory accesses (e.g., writes and/or reads). Techniques are disclosed herein for mitigating leakage current in the cross-point array. In an embodiment, the slope of a trailing edge of a pulse for Vs applied to the selected word line depends on the wear (e.g., number of write and/or read accesses) of the selected memory cell. In one embodiment, the slope of the trailing edge of a Vs pulse is made greater with more of one or more types of memory accesses (e.g., writes and/or reads) to the selected memory cell.

In the example of FIG. 7 there are more word lines than bit lines in the cross-point array. In another embodiment, there are more bit lines than word lines in the cross-point array. In another embodiment, the number of bit lines equals the number of word lines in the cross-point array. In the example of FIG. 7 there are twice as many word lines as bit lines in the cross-point array; however, a different ratio could be used. Thereby, different tile sizes may be realized. For example, a tile may have 1024 BL by 2048 WL, which may be composed into a module of 2048×4096 cells by center driving the WL and BL between the four tiles. In one embodiment, forming is performed on a group of memory cell by, for example, selecting one memory cell in each of a number of tiles.

In some embodiments, a voltage-force technique is used to access memory cells in a cross-point memory array. In other embodiments, a current-force approach is used to access memory cells in a cross-point memory array. In an embodiment of a current-force approach, a current is applied to the selected word line, as opposed to applying a voltage to the selected word line. However, voltages may still be applied to the selected bit line and to the unselected word lines and the unselected bit lines, similar to the voltage-force approach. To select memory cell 401a, a select voltage (V_{select_BL}) such as near ground is provided to the selected bit line (e.g., bit line 708b) and an access current (I_{access}) is driven (or forced) to a selected word line (e.g., word line 706g). The access current charges up the voltage on the selected word line 706g. There is a limit to how high the voltage on the selected word line 706g may reach (e.g., a compliance voltage). In one embodiment, V_{select_BL} has an adequate magnitude such that the threshold switching selector 502 in a selected memory cell will turn on, assuming that I_{access} is applied to the selected word line with adequate compliance voltage relative to the BL voltage. For example, V_{select_BL} may be approximately 0V. On the other hand, V_{unsel_BL} has a magnitude such that the threshold switching selector 502 in an unselected memory cell will not turn on, for example V_{unsel_BL} may be approximately 1.65V if the positive power supply is 3.3V. Access current (I_{access}) is driven through at least a portion of selected word line 706g after the OTS is turned on. This access current may also flow through the selected memory cell 401 a and in a portion of selected bit line 708b after the OTS is turned on. Such a selected WL may, for example, be driven high by 15 μA to read or 30 μA to write by a current source with compliance voltage of, for example, 3.3 V. To write the opposite polarity, the selected word line is forced, for example, with −30 μA and the selected bit line to near 3.3 V.

Word lines and bit lines that are not selected are referred to as unselected word lines or unselected bit lines, respectively. In one embodiment, a word line or bit line may be unselected by forcing them to an unselect voltage, such as Vmid, for example 1.65 V, at approximately one half the drive compliance voltage; e.g., 3.3 V. An unselect voltage (V_{unsel_BL}) is provided to the unselected bit lines (e.g., bit lines 708a, 708c, 708d). An unselect voltage (V_{unsel_WL}) such as Vmid is provided to the unselected word lines (e.g., word lines 706a, 706b, 706c, 706d, 706e, 706f, and 706h). I_{access} could flow in either direction through the selected word line (as well as the selected bit line). In one embodiment, no current other than leakage is forced through unselected word lines (e.g., 706a, 706b, 706c, 706d, 706e, 706f, and 706h).

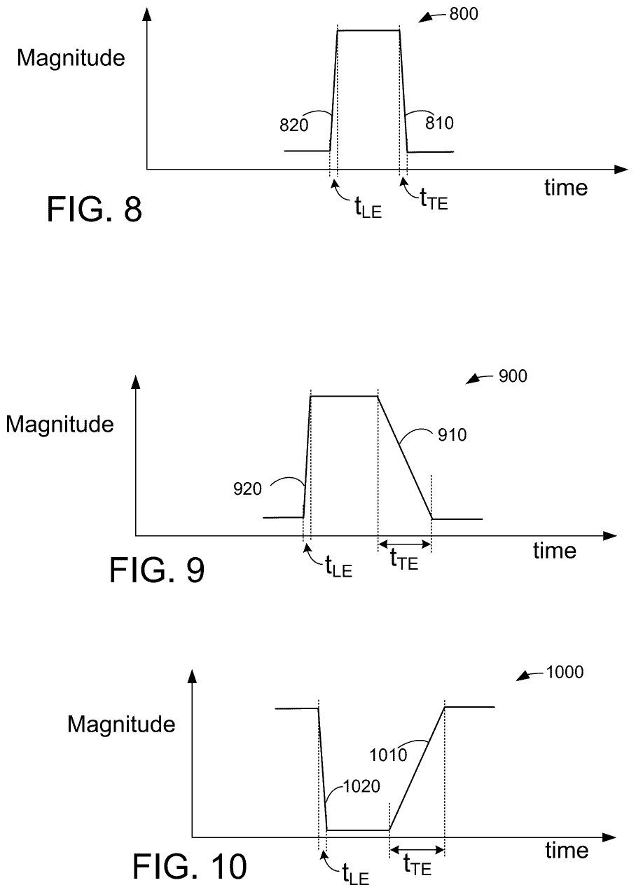

FIG. 8 depicts a conventional pulse 800 that may be applied to a programmable resistance memory cell in a cross point array. The pulse 800 has a trailing edge (TE) 810 with a relatively fast fall time (t_{TE}). The pulse 800 has a leading edge (TE) 820 with a relatively fast rise time (t_{LE}). The rise time and fall time may be about the same. As one example, the rise and fall times may be about 10 nanoseconds (ns). The pulse 800 could be a voltage pulse applied to a selected word line while a select voltage is applied to a selected bit line.

FIG. 9 depicts a pulse 900 that is applied to a programmable resistance memory cell in a cross point array by an embodiment of a memory system. The pulse 900 has a trailing edge (TE) 910 with a relatively slow fall time (t_{TE}). Note that the slope of the TE 910 may be adjusted over time. The pulse 900 has a leading edge 920 with a relatively fast rise time (t_{TE}). In an embodiment, the TE 910 fall time (t_{TE}) is significantly longer than the leading edge 920 rise time (t_{LE}). In an embodiment, the leading edge 920 rise time (t_{TE}) is about 10 ns and the TE 910 fall time (t_{TE}) is longer than 10 ns. For example, the TE 910 fall time (t_{TE}) may be about 20 ns to 100 ns. However, the TE 910 fall time (TE) may be about less than 20 ns or greater than 100 ns. The slope of the TE 910 is relatively low compared to the slope of the leading edge 920. Also, the slope (in absolute value) of the TE 910 is relatively low compared to the slope (in absolute value) of the TE 810 of pulse 800 in FIG. 8. Stated another way, TE 910 has a flatter slope than leading edge 920. Also, TE 910 has a flatter slope than TE 810 of pulse 800. In an embodiment, the pulse 900 is a voltage pulse applied to a selected word line while a select voltage (e.g., 0V) is applied to a selected bit line. In an embodiment, the pulse 900 is a current pulse applied to a selected word line while a select voltage (e.g., 0V) is applied to a selected bit line. Alternatively, the pulse 900 could be applied to a selected bit line while a selected word line receives a select voltage. In this example, the select voltage is 0V, but the select voltage could be other than 0V.

FIG. 10 depicts a pulse 1000 that is applied to a programmable resistance memory cell in a cross point array by an embodiment of a memory system. The pulse 1000 has a trailing edge (TE) 1010 with a relatively flow rise time (t_{TE}). However, the leading edge (TE) 1020 has a relatively fast fall time (t_{LE}). In an embodiment, the TE 1010 rise time (t_{TE}) is significantly longer than the leading edge 1020 fall time (t_{LE}). In an embodiment, the leading edge 1020 fall time (t_{TE}) is about 10 ns and the TE 1010 rise time (t_{TE}) is longer than 10 ns. For example, the TE 1010 rise time (t_{TE}) may be about 20 ns to 100 ns. However, the TE 1010 rise time (t_{TE}) may be about less than 20 ns or greater than 100 ns. The slope of the TE 1010 is relatively low compared to the slope of the leading edge 1020. Also, the slope of the TE 1010 is relatively low compared to the slope (in absolute value) of the TE 810 of pulse 800 in FIG. 8. Stated another way, TE 910 has a flatter slope than leading edge 1020. Also, TE 1010 has a flatter slope than TE 810 of pulse 800. In an embodiment, the pulse 1000 is a voltage pulse applied to a selected word line while a select voltage (e.g., 0V) is applied to a selected bit line. In an embodiment, the pulse 1000 is a current pulse applied to a selected word line while a select voltage (e.g., 0V) is applied to a selected bit line. Alternatively, the pulse 1000 could be applied to a selected bit line while a selected word line receives a select voltage. In this example, the select voltage is OV, but the select voltage could be other than OV.

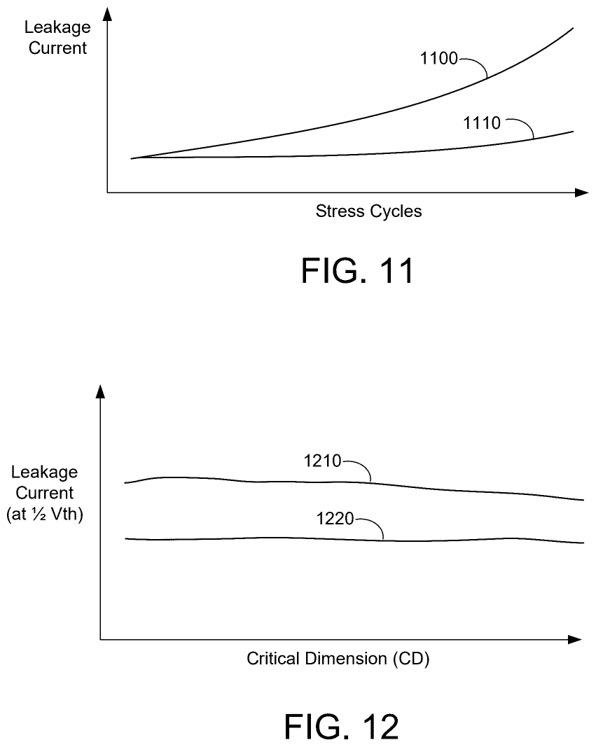

The leakage current in a cross-point memory array having programmable resistance memory cells with threshold switching selectors tends to increase with use. FIG. 11 depicts plots of leakage current versus stress cycles. Plot 1100 is an example of leakage current without compensation. Plot 1110 is an example of leakage current with compensation provided by an embodiment of a memory system. An example of a stress cycle is to apply a positive voltage to a memory cell followed by a negative voltage (or the reverse). This stress cycle simulates either a write to the HRS followed by a write to the LRS (or the reverse). Plot 1100 shows that the leakage current increases significantly with increased cycling without compensation provided by an embodiment of a memory system. Plot 1110 shows that compensation provided by an embodiment of a memory system reduces the increase in leakage current that might otherwise occur. There may be a specification defining an upper limit for leakage current. The compensation provided by an embodiment of a memory system keeps the leakage current within such as specification. Without compensation the leakage current may exceed such as specification. The shape of plots 1100 and 1110 will depend on many factors, wherein plots 1100 and 1110 are for the purpose of illustration of the effect of cycling on leakage current.

In an embodiment, the slope (in absolute value) of the trailing edge (TE) of a pulse applied to a selected programmable resistance memory cell is decreased (e.g., a longer fall time or flatter slope) in order to reduce leakage current. FIG. 12 depicts leakage current versus critical dimension (CD) of the memory cells for two different slopes of the trailing edge of the pulse applied to the selected memory cell. The leakage current is for a voltage pulse having a magnitude that is ½ the Vth of threshold switching selector. Plot 1210 is for a “fast trailing edge (TE)” and plot 1220 is for a “slow trailing edge (TE).” The slope (in absolute value) of the fast TE is greater than the slope (in absolute value) of the slow TE. Stated another way, the slow TE has a flatter slope than the fast TE. For example, the ramp down time of the fast TE is shorter than the ramp down time of the slow TE. However, the pulse could have a positive polarity or a negative polarity. Thus, alternatively, the ramp up time of the fast TE is shorter than the ramp up time of the slow TE. The leakage current is significantly lower for the slow TE than for the fast TE.

Another factor that may impact leakage current is the critical dimension (CD) of the threshold switching selector. The leakage current may increase with a smaller CD. It is desirable to have a smaller CD to increase bit density. Therefore, leakage current may become a greater problem as the size of programmable resistance memory cells with threshold switching selectors is made smaller.

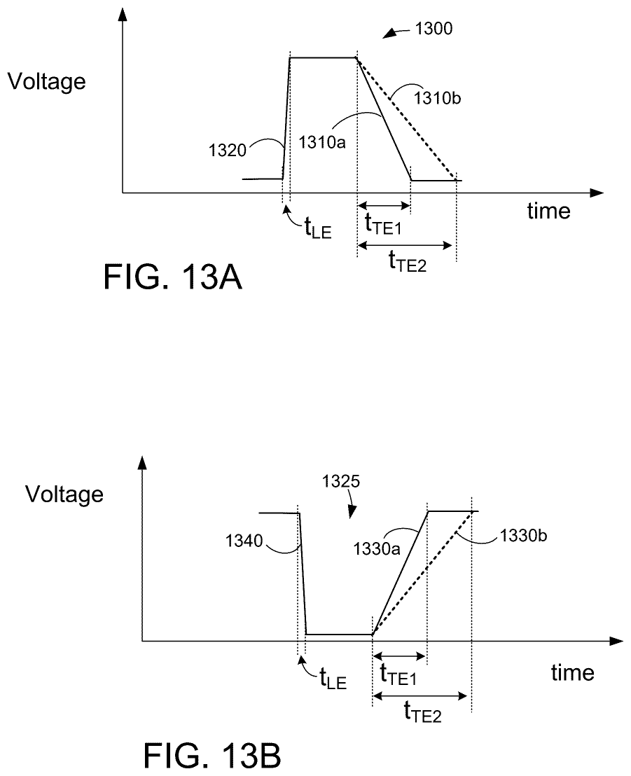

In an embodiment, the memory system applies a voltage pulse to the memory cell, wherein the slope of the TE of the pulse depends on a wear factor of the memory cell. FIG. 13A depicts a voltage pulse 1300 applied to a memory cell by an embodiment of a memory system. The voltage pulse has a sufficiently high magnitude to turn on the threshold switching selector of the selected memory cell. In an embodiment, the voltage pulse is applied to a selected word line while a select voltage is applied to a selected bit line. In an embodiment, the voltage pulse is used to write the memory cell to a particular resistance state. For example, the voltage pulse might be used to program the memory cell to the HRS. In an embodiment, the voltage pulse is used to read the memory cell. Two different TEs are depicted 1310a, 1310b for voltage pulse 1300. Trailing edge 1310a has a shorter fall time (t_{TE1}) than the fall time (t_{TE2}) of TE 1310b. Stated another way, TE 1310b has a flatter slope than TE 1310a. Both fall times (t_{TE1}) and (t_{TE2}) are longer than the rise time (t_{LE}) of the leading edge 1320. IIn an embodiment, the memory system will lengthen the fall time (e.g., flatten the slope) of the TE as the wear factor of the memory cell increases. In an embodiment, the wear factor is based on a number of program cycles. Thus, the memory system may increase the fall time (e.g., flatten the slope) as the number of program cycles increases. Although FIG. 13A depicts two different slopes for the TE 1310, over time the memory system may use more than two different slopes for the TE 1310.

FIG. 13B depicts embodiments of a voltage pulse 1325 having the opposite polarity as the pulse 1300 in FIG. 13A. The voltage pulse 1325 has a sufficiently high magnitude (in absolute value) to turn on the threshold switching selector of the selected memory cell. In an embodiment, the voltage pulse is applied to a selected word line while a select voltage is applied to a selected bit line. In an embodiment, the voltage pulse is used to write the memory cell to a particular resistance state. For example, the voltage pulse 1325 might be used to program the memory cell to a different resistance state than pulse 1300. Thus, if voltage pulse 1300 writes the memory cell to the HRS then voltage pulse 1325 may write the memory cell to the LRS. In some embodiments, the voltage pulse 1325 is used to read the memory cell. However, note that it is not required to use both voltage pulse 1325 and voltage pulse 1300 to read the memory cell. Two different TEs are depicted 1330a, 1330b for voltage pulse 1325. Trailing edge 1330a has a shorter rise time (t_{TE1}) than the rise time (t_{TE2}) of TE 1330b. Stated another way, TE 1330b has a flatter slope than TE 1330a. Both rise times (t_{TE1}) and (t_{TE2}) are longer than the fall time (t_{LE}) of the leading edge 1340. IIn an embodiment, the memory system will lengthen the rise time (e.g., flatten the slope) of the TE as the wear factor of the memory cell increases. In an embodiment, the wear factor is based on a number of program cycles. Thus, the memory system may increase the fall time (e.g., flatten the slope) as the number of program cycles increases. Although FIG. 13B depicts two different slopes for the TE 1330, over time the memory system may use more than two different slopes for the TE 1330.

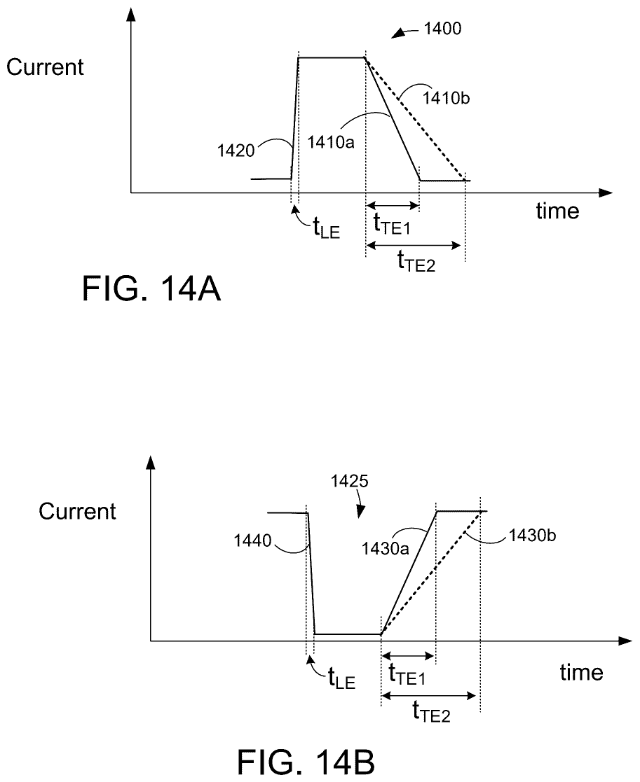

In an embodiment, the memory system applies a current pulse to the memory cell, wherein the slope of the TE of the current pulse depends on a wear factor of the memory cell. FIG. 14A depicts a current pulse 1400 applied to a memory cell by an embodiment of a memory system. The current pulse has a sufficiently high magnitude to turn on the threshold switching selector of the selected memory cell. In an embodiment, the current pulse is applied to a selected word line while a select voltage is applied to a selected bit line. The current pulse will charge up the voltage on the selected word line to turn on the threshold switching selector of the selected memory cell. In an embodiment, the current pulse is used to write the memory cell to a particular resistance state. For example, the current pulse might be used to program the memory cell to the HRS. In an embodiment, the current pulse is used to read the memory cell. Two different TEs are depicted 1410a, 1410b for current pulse 1400. Trailing edge 1410a has a shorter fall time (t_{TE1}) than the fall time (t_{TE2}) of TE 1410b. Stated another way, TE 1410b has a flatter slope than TE 1410a. Both fall times (t_{TE1}) and (t_{TE2}) are longer than the rise time (t_{LE}) of the leading edge 1420. In an embodiment, the memory system will lengthen the fall time (e.g., flatten the slope) of the TE as the wear factor of the memory cell increases. In an embodiment, the wear factor is based on a number of program cycles. Thus, the memory system may increase the fall time (e.g., flatten the slope) as the number of program cycles increases. Although FIG. 14A depicts two different slopes for the TE 1410, over time the memory system may use more than two different slopes for the TE 1410.

FIG. 14B depicts embodiments of a current pulse 1425 having the opposite polarity as the current pulse 1400 in FIG. 14A. The current pulse 1425 has a sufficiently high magnitude (in absolute value) to turn on the threshold switching selector of the selected memory cell. In an embodiment, the current pulse 1425 is applied to a selected word line while a select voltage is applied to a selected bit line. The current pulse 1425 will charge up the voltage on the selected word line to turn on the threshold switching selector of the selected memory cell. In an embodiment, the current pulse is used to write the memory cell to a particular resistance state. For example, the current pulse 1425 might be used to program the memory cell to a different resistance state than pulse 1400. Thus, if current pulse 1400 writes the memory cell to the HRS then current pulse 1425 may write the memory cell to the LRS. In some embodiments, the current pulse 1425 is used to read the memory cell. However, note that it is not required to use both current pulse 1425 and current pulse 1400 to read the memory cell. Two different TEs are depicted 1430a, 1430b for current pulse 1425. Trailing edge 1430a has a shorter rise time (t_{TE1}) than the rise time (t_{TE2}) of TE 1430b. Stated another way, TE 1430b has a flatter slope than TE 1430a. Both rise times (t_{TE1}) and (t_{TE2}) are longer than the fall time (t_{LE}) of the leading edge 1440. In an embodiment, the memory system will lengthen the rise time (e.g., flatten the slope) of the TE as the wear factor of the memory cell increases. In an embodiment, the wear factor is based on a number of program cycles. Thus, the memory system may increase the fall time (e.g., flatten the slope) as the number of program cycles increases. Although FIG. 14B depicts two different slopes for the TE 1430, over time the memory system may use more than two different slopes for the TE 1430.

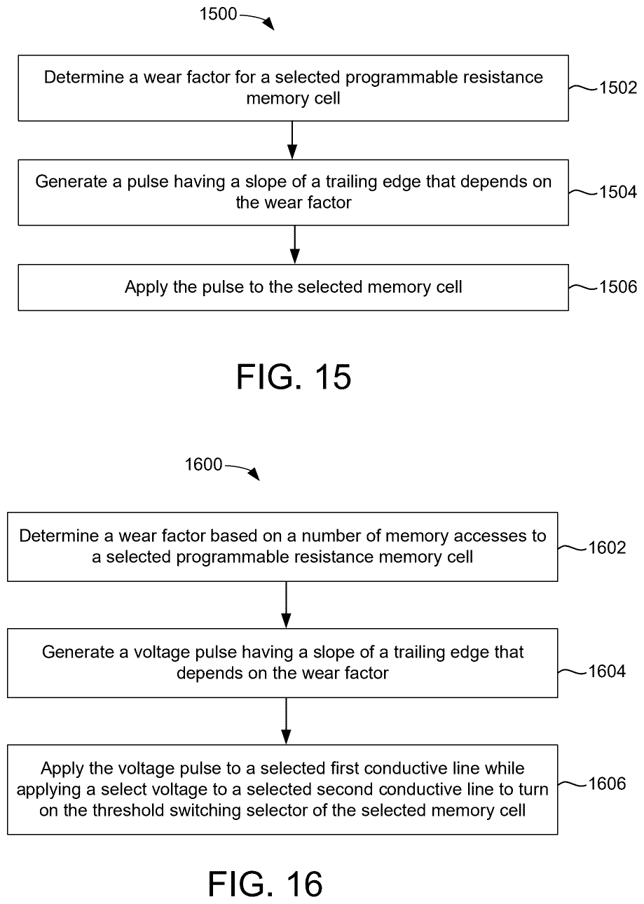

FIG. 15 is a flowchart of one embodiment of a process 1500 for reducing leakage current when operating a cross-point array. The memory cells in the cross-point array are programmable resistance cells and each have a two-terminal threshold switching selector. In an embodiment, the two-terminal threshold switching selector is in series with a programmable resistance memory element such as a magnetic tunnel junction. In an embodiment, the two-terminal threshold switching selector serves as the programmable resistance memory element.

Step 1502 includes determining a wear factor for a selected programmable resistance memory cell. In an embodiment, the wear factor is based on how many times the memory cell has been accessed (e.g., writes and/or reads). The memory system may track the wear for the cross-point array in general and need not track the wear for each memory cell individually. For example, the memory system may track the number of memory accesses to the cross-point array, wherein each memory cell in the cross-point array could be given the same wear factor. However, tracking wear (e.g., memory accesses) on a level of granularity lower than the cross-point array is not precluded.

Step 1504 includes generating a pulse having a trailing edge (TE) slope that depends on the wear factor. In an embodiment, the pulse is a voltage pulse. In an embodiment, the pulse is a current pulse. In an embodiment, the pulse is used to write the memory cell to a resistance state. In an embodiment, the pulse is used to read a resistance state from the memory cell. Example pulses are depicted in FIGS. 9, 10, 13A, 13B, 14A, and 14B. In an embodiment, the memory system uses at least two different slopes for the TE of the pulse depending on the wear factor. As one example, after a certain number of stress cycles (e.g., memory accesses) the memory system may flatten the slope of the TE. As one example, a table driven approach is used in which a slope is specified for each of a number of stress cycles.

Step 1506 includes applying the pulse to the selected memory cell. In an embodiment, the pulse is applied to a selected word line while a select voltage is applied to a selected bit line. In an embodiment, the pulse is applied to a selected bit line while a select voltage is applied to a selected word line. The selected memory cell is connected between the selected word line and the selected bit line.

FIG. 16 is a flowchart of one embodiment of a process 1600 for reducing leakage current when operating a cross-point array. Process 1600 provides further details for an embodiment of process 1500. The memory cells in the cross-point array are programmable resistance cells and each have a two-terminal threshold switching selector. In an embodiment, the two-terminal threshold switching selector is in series with a programmable resistance memory element such as a magnetic tunnel junction. In an embodiment, the two-terminal threshold switching selector serves as the programmable resistance memory element.

Step 1602 includes determining a wear factor based on a number of memory accesses to a selected programmable resistance memory cell. The number of memory accesses is used as an indirect measure of increase in leakage current. Therefore, the techniques for counting memory accesses may be based on expected impact of the memory access on leakage. For example, a write pulse typically has a significantly higher magnitude than a read pulse and may therefore have a different expected impact on wear. Thus, reads could be given a different weight than writes.

Step 1604 includes generating a voltage pulse having a trailing edge (TE) slope that depends on the wear factor. Example pulses are depicted in FIGS. 13A and 13B. The slope of the TE of the voltage pulse will be flatter with a greater wear. For example, the slope of the TE of the voltage pulse will be flatter with a greater number of memory accesses.

Step 1606 includes applying the voltage pulse to a selected first conductive line while applying a select voltage to a selected second conductive line. Step 1606 results in the threshold switching selector in the selected memory cell turning on. In an embodiment, the selected first conductive line is a word line and the selected second conductive line is a bit line. In an embodiment, the selected first conductive line is a bit line and the selected second conductive line is a word line.

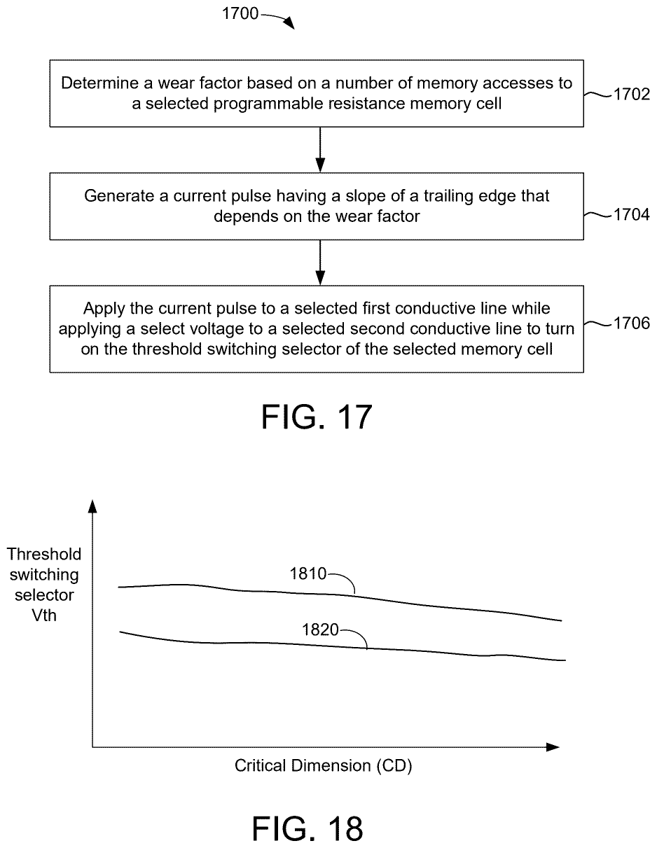

FIG. 17 is a flowchart of one embodiment of a process 1700 for reducing leakage current when operating a cross-point array. Process 1700 provides further details for an embodiment of process 1500. The memory cells in the cross-point array are programmable resistance cells and each have a two-terminal threshold switching selector. In an embodiment, the two-terminal threshold switching selector is in series with a programmable resistance memory element such as a magnetic tunnel junction. In an embodiment, the two-terminal threshold switching selector serves as the programmable resistance memory element.

Step 1702 includes determining a wear factor based on a number of memory accesses to a selected programmable resistance memory cell. The number of memory accesses is used as an indirect measure of increase in leakage current. Therefore, the techniques for counting memory accesses may be based on expected impact of the memory access on leakage. For example, a write pulse typically has a significantly higher magnitude than a read pulse and may therefore have a different expected impact on wear. Thus, reads could be given a different weight than writes.

Step 1704 includes generating a current pulse having a trailing edge (TE) slope that depends on the wear factor. Example pulses are depicted in FIGS. 14A and 14B. The slope of the TE of the current pulse will be flatter with a greater wear. For example, the slope of the TE of the current pulse will be flatter with a greater number of memory accesses.

Step 1706 includes applying the current pulse to a selected first conductive line while applying a select voltage to a selected second conductive line. Step 1706 results in the threshold switching selector in the selected memory cell turning on. In an embodiment, the selected first conductive line is a word line and the selected second conductive line is a bit line. In an embodiment, the selected first conductive line is a bit line and the selected second conductive line is a word line.

The slope of the TE of the pulse may also provide technical benefits with respect to the snapback effect. The snapback effect occurs as a result of the rapid drop of voltage across the threshold switching selector when it turns on. When the threshold switching selector turns on, the voltage across the threshold switching selector drops from its Vth to its on voltage (Voffset). This rapid drop in voltage may result in a snapback current, which is undesirable and may disturb the state of the programmable resistance memory element. FIG. 18 depicts plots of threshold switching selector Vth versus critical dimension (CD). Plot 1810 is Vth versus CD without compensation to the slope of the TE of the pulse provided by an embodiment of a memory system. Plot 1820 is Vth versus CD with compensation to the slope of the TE of the pulse provided by an embodiment of a memory system. For example, plot 1810 is for a conventional pulse 800 in FIG. 8 having a “fast TE”. Plot 1820 is for a pulse having a “slow TE”, such as in any of FIGS. 9, 10, 13A, 13B, 14A, or 14B. For any CD, the Vth is lower for the slow TE plot 1820 than for the fast TE plot 1810. The lower Vth helps to reduce the snapback effect by reducing the difference between the Vth and Voffset. FIG. 18 also depicts an increase in leakage current with smaller CDs. Smaller CDs help to increase bit density, but could have higher leakage current. Therefore, mitigating the leakage current as described herein allows for a reduction in CD while still meeting leakage current specifications.

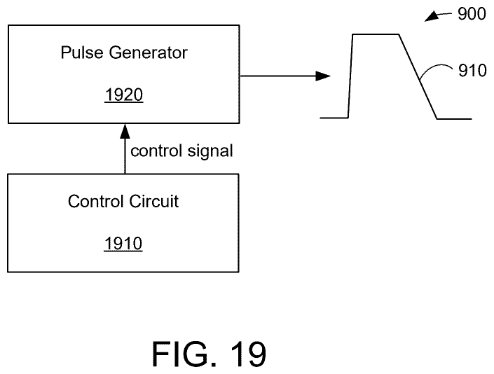

FIG. 19 is a block level diagram of an embodiment of components for generating a pulse having target slope for the TE. The pulse generator 1920 is configured to generate a pulse 900 having a target slope for the TE 910. The pulse generator 1920 may also be able to output a negative pulse (see FIG. 10), but that is not depicted in FIG. 19. As an example, the pulse generator 1920 may adjust resistance and/or capacitance values to control the slope of the TE 910. In an embodiment, the pulse generator 1920 comprises a voltage generator configured to output a voltage pulse (e.g., voltage pulse 1300, 1325). In an embodiment, the pulse generator 1920 comprises a current generator configured to output a current pulse (e.g., current pulse 1400, 1425). The control circuit 1910 issues a control signal to control the pulse generator 1920. The control circuit 1910 may factor in the number of memory accesses (e.g., writes and/or reads) to determine the value for the control signal.

In view of the foregoing, it can be seen that, according to an embodiment, an apparatus comprises a cross-point memory array a plurality of first conductive lines, a plurality of second conductive lines, and magnetoresistive random access memory (MRAM) cells. Each MRAM cell is connected between one of the first conductive lines and one of the second conductive lines. Each MRAM cell has a two-terminal threshold switching selector in series with a magnetic tunnel junction. The apparatus comprises one or more control circuits in communication with the cross-point memory array. The one or more control circuits are configured to determine a wear factor for a selected MRAM cell. The one or more control circuits are configured to generate a pulse to apply to a selected MRAM cell, wherein a slope of a trailing edge of the pulse depends on the wear factor. The one or more control circuits are configured to apply the pulse to the selected MRAM cell.

In a further embodiment, the one or more control circuits are configured to decrease an absolute value of the slope of the trailing edge of the pulse as the wear factor indicates greater wear to the selected MRAM cell.

In a further embodiment, the wear factor increases with a greater number of memory accesses to the selected MRAM cell.

In a further embodiment, the pulse comprises a programming pulse.

In a further embodiment, the programming pulse is configured to write the magnetic tunnel junction in the selected MRAM cell to a high resistance state (HRS).

In a further embodiment, the programming pulse is configured to write the magnetic tunnel junction in the selected MRAM cell to a low resistance state (LRS).

In a further embodiment, the programming pulse is a first programming pulse configured to write the selected MRAM cell to the LRS. The one or more control circuits are configured to generate a second programming pulse to apply to the selected MRAM cell, wherein a slope of a trailing edge of the second programming pulse depends on the wear factor. And the one or more control circuits are configured to apply the second programming pulse to the selected MRAM cell to write the magnetic tunnel junction in the selected MRAM cell to a high resistance state (HRS).

In a further embodiment, the pulse comprises a read pulse configured to read a resistance of the magnetic tunnel junction in the selected MRAM cell. In a further embodiment, a duration of the trailing edge of the pulse is at least 100 nanoseconds.

In a further embodiment, the pulse comprises a voltage pulse and the one or more control circuits are configured to apply the voltage pulse to a selected first conductive line connected to the selected MRAM cell while applying a select voltage to a selected second conductive line connected to the selected MRAM cell to turn on the two-terminal threshold switching selector of the selected MRAM cell.

In a further embodiment, the pulse comprises a current pulse and the one or more control circuits are configured to apply the current pulse to a selected first conductive line connected to the selected MRAM cell while applying a select voltage to a selected second conductive line connected to the selected MRAM cell to turn on the two-terminal threshold switching selector of the selected MRAM cell.

In a further embodiment, an absolute value of the slope of the trailing edge of the pulse is less than an absolute value of a slope of a leading edge of the pulse.

In a further embodiment, the trailing edge of the pulse is a falling edge.

In a further embodiment, the trailing edge of the pulse is a rising edge.

In a further embodiment, the two-terminal threshold switching selector comprises an Ovonic Threshold Switch (OTS).

An embodiment includes a method for operating a cross-point memory array having magnetoresistive random access memory (MRAM) cells, each MRAM cell connected between one of a plurality of first conductive lines and one of a plurality of second conductive lines. The method comprises determining a slope for a pulse based on a number of memory accesses performed on a selected MRAM cell. An absolute value of the slope increases with increases in the number of memory accesses. The method comprises generating the pulse having the slope. The method comprises applying the pulse to a first conductive line connected to the selected MRAM cell while applying a select voltage to a second conductive line connected to the selected MRAM cell to turn on a two-terminal threshold switching selector of the selected MRAM cell.

An embodiment includes a memory system comprising a cross-point memory array a plurality of first conductive lines, a plurality of second conductive lines, and MRAM cells. Each MRAM cell is connected between one of the first conductive lines and one of the second conductive lines. Each MRAM cell has a two-terminal threshold switching selector in series with a magnetic tunnel junction. The memory system comprises one or more control circuits in communication with the cross-point memory array. The one or more control circuits are configured to track memory accesses performed on a selected MRAM cell connected between a selected first conductive line and a selected second conductive line. The one or more control circuits are configured to generate a pulse having a trailing edge having a duration that depends on the memory accesses. The pulse has a peak magnitude greater than a threshold voltage of the threshold switching selector in the selected MRAM cell. The one or more control circuits are configured to apply the pulse to the selected first conductive line while applying a select voltage to the selected second conductive line to switch on the threshold switching selector in the selected MRAM cell.

For purposes of this document, reference in the specification to “an embodiment,” “one embodiment,” “some embodiments,” or “another embodiment” may be used to describe different embodiments or the same embodiment.

For purposes of this document, a connection may be a direct connection or an indirect connection (e.g., via one or more other parts). In some cases, when an element is referred to as being connected or coupled to another element, the element may be directly connected to the other element or indirectly connected to the other element via intervening elements. When an element is referred to as being directly connected to another element, then there are no intervening elements between the element and the other element. Two devices are “in communication” if they are directly or indirectly connected so that they can communicate electronic signals between them.

For purposes of this document, the term “based on” may be read as “based at least in part on.”

For purposes of this document, without additional context, use of numerical terms such as a “first” object, a “second” object, and a “third” object may not imply an ordering of objects, but may instead be used for identification purposes to identify different objects.

terms “top” and “bottom,” “upper” and “lower” and “vertical” and “horizontal,” and forms thereof, as may be used herein are by way of example and illustrative purposes only, and are not meant to limit the description of the technology inasmuch as the referenced item can be exchanged in position and orientation. Also, as used herein, the terms “substantially” and/or “about” mean that the specified dimension or parameter may be varied within an acceptable tolerance for a given application.

The foregoing detailed description has been presented for purposes of illustration and description. It is not intended to be exhaustive or to limit to the precise form disclosed. Many modifications and variations are possible in light of the above teaching. The described embodiments were chosen in order to best explain the principles of the proposed technology and its practical application, to thereby enable others skilled in the art to best utilize it in various embodiments and with various modifications as are suited to the particular use contemplated. It is intended that the scope be defined by the claims appended hereto.

What is claimed is:

1. An apparatus comprising:
a cross-point memory array a plurality of first conductive lines, a plurality of second conductive lines, and magnetoresistive random access memory (MRAM) cells, each MRAM cell connected between one of the first conductive lines and one of the second conductive lines, each MRAM cell having a two-terminal threshold switching selector in series with a magnetic tunnel junction; and
one or more control circuits in communication with the cross-point memory array, the one or more control circuits configured to:
determine a wear factor for a selected MRAM cell;
generate a pulse to apply to a selected MRAM cell, wherein a slope of a trailing edge of the pulse depends on the wear factor; and
apply the pulse to the selected MRAM cell.

2. The apparatus of claim 1, wherein the one or more control circuits are configured to decrease an absolute value of the slope of the trailing edge of the pulse as the wear factor indicates greater wear to the selected MRAM cell.

3. The apparatus of claim 2, wherein the wear factor increases with a greater number of memory accesses to the selected MRAM cell.

4. The apparatus of claim 1, wherein the pulse comprises a programming pulse.

5. The apparatus of claim 4, wherein the programming pulse is configured to write the magnetic tunnel junction in the selected MRAM cell to a high resistance state (HRS).

6. The apparatus of claim 4, wherein the programming pulse is configured to write the magnetic tunnel junction in the selected MRAM cell to a low resistance state (LRS).

7. The apparatus of claim 6, wherein:
the programming pulse is a first programming pulse configured to write the selected MRAM cell to the LRS;
the one or more control circuits are configured to:
generate a second programming pulse to apply to the selected MRAM cell, wherein a slope of a trailing edge of the second programming pulse depends on the wear factor; and
apply the second programming pulse to the selected MRAM cell to write the magnetic tunnel junction in the selected MRAM cell to a high resistance state (HRS).

8. The apparatus of claim 1, wherein the pulse comprises a read pulse configured to read a resistance of the magnetic tunnel junction in the selected MRAM cell.

9. The apparatus of claim 1, wherein a duration of the trailing edge of the pulse is at least 100 nanoseconds.

10. The apparatus of claim 1, wherein the pulse comprises a voltage pulse and the one or more control circuits are configured to:
apply the voltage pulse to a selected first conductive line connected to the selected MRAM cell while applying a select voltage to a selected second conductive line connected to the selected MRAM cell to turn on the two-terminal threshold switching selector of the selected MRAM cell.

11. The apparatus of claim 1, wherein the pulse comprises a current pulse and the one or more control circuits are configured to:
apply the current pulse to a selected first conductive line connected to the selected MRAM cell while applying a select voltage to a selected second conductive line connected to the selected MRAM cell to turn on the two-terminal threshold switching selector of the selected MRAM cell.

12. The apparatus of claim 1, wherein an absolute value of the slope of the trailing edge of the pulse is less than an absolute value of a slope of a leading edge of the pulse.

13. The apparatus of claim 1, wherein the trailing edge of the pulse is a falling edge.

14. The apparatus of claim 1, wherein the trailing edge of the pulse is a rising edge.

15. The apparatus of claim 1, wherein the two-terminal threshold switching selector comprises an Ovonic Threshold Switch (OTS).

16. A method for operating a cross-point memory array having magnetoresistive random access memory (MRAM) cells, each MRAM cell connected between one of a plurality of first conductive lines and one of a plurality of second conductive lines, the method comprising:
determining a slope for a pulse based on a number of memory accesses performed on a selected MRAM cell, wherein an absolute value of the slope increases with increases in the number of memory accesses;
generating the pulse having the slope; and
applying the pulse to a first conductive line connected to the selected MRAM cell while applying a select voltage to a second conductive line connected to the selected MRAM cell to turn on a two-terminal threshold switching selector of the selected MRAM cell.

17. A memory system comprising:
a cross-point memory array a plurality of first conductive lines, a plurality of second conductive lines, and MRAM cells, each MRAM cell connected between one of the first conductive lines and one of the second conductive lines, each MRAM cell having a two-terminal threshold switching selector in series with a magnetic tunnel junction; and
one or more control circuits in communication with the cross-point memory array, the one or more control circuits configured to:
track memory accesses performed on a selected MRAM cell connected between a selected first conductive line and a selected second conductive line;
generate a pulse having a trailing edge having a duration that depends on the memory accesses, the pulse having a peak magnitude greater than a threshold voltage of the threshold switching selector in the selected MRAM cell; and
apply the pulse to the selected first conductive line while applying a select voltage to the selected second conductive line to switch on the threshold switching selector in selected MRAM cell.

18. The memory system of claim 17, wherein the one or more control circuits increase the duration of the trailing edge with an increase in a number of the memory accesses to the selected MRAM cell.

19. The memory system of claim 17, wherein the pulse is a voltage pulse.

20. The memory system of claim 17, wherein the pulse is a current pulse.
